(19) United States
(12) Patent Application Publication
(10) Pub. No.: US 2025/0212404 A1
(43) Pub. Date: Jun. 26, 2025

(54) INTEGRATED FLASH MEMORY AND COMPLEMENTARY FIELD EFFECT TRANSITOR SEMICONDUCTOR PROCESSING

(71) Applicant: TEXAS INSTRUMENTS INCORPORATED, Dallas, TX (US)

(72) Inventors: Jonathan Lane, Sandy, UT (US); Giulio Albini, Draper, UT (US); Robert Cassel, Lehi, UT (US)

(21) Appl. No.: 18/393,286

(22) Filed: Dec. 21, 2023

(51) Int. Cl. H10B 41/42; H01L 21/28; H01L 29/423; H01L 29/66; H01L 29/788; H10B 41/30

(52) U.S. Cl. CPC H10B 41/42; H10B 41/30; H10D 30/0411; H10D 30/683; H10D 30/6892; H10D 64/035

(57) ABSTRACT

The present disclosure generally relates to an integrated circuit (IC) including a flash memory bit structure. In an example, an IC includes a flash memory bit structure and a transistor structure. The flash memory bit structure is on a semiconductor substrate. The flash memory bit structure includes a word line structure and a first oxide layer disposed between the semiconductor substrate and the word line structure. The first oxide layer is free of nitridation. The transistor structure is on the semiconductor substrate. The transistor structure includes a gate structure and a gate oxide layer including nitridation. The gate oxide layer is over the semiconductor substrate. The gate structure is over the gate oxide layer.

### BACKGROUND

A non-volatile memory (NVM) bitcell is an electronic element that is configured to store information. A threshold voltage can be used to discriminate between logic levels of the bitcell, such as a logic low level (“0”) or a logic high level (“1”). This stored value may sometimes be referred to as information (or a bit), which may be read by sense amplifier circuitry. Although integrating an NVM array with additional circuitry, e.g., logic circuitry, in the same integrated circuit (IC) is a desirable goal for the semiconductor manufacturing industry, it is not without challenges.

### SUMMARY

An example described herein is an integrated circuit (IC). The IC includes a flash memory bit structure and a transistor structure. The flash memory bit structure is on a semiconductor substrate. The flash memory bit structure includes a word line structure and a first oxide layer disposed between the semiconductor substrate and the word line structure. The first oxide layer is free of nitridation. The transistor structure is on the semiconductor substrate. The transistor structure includes a gate structure and a gate oxide layer including nitridation. The gate oxide layer is over the semiconductor substrate. The gate structure is over the gate oxide layer.

Another example is a method. A flash memory bit structure is formed on a semiconductor substrate. Forming the flash memory bit structure includes forming a floating gate structure over the semiconductor substrate; forming a first oxide layer at a first side of the floating gate structure; and forming a word line structure on the first oxide layer. The first oxide layer is between the word line structure and the semiconductor substrate. After forming the word line structure, a gate oxide layer of a transistor structure is formed on the semiconductor substrate.

A further example is a method. A floating gate structure is formed over a semiconductor substrate. An oxide-nitride-oxide stack is formed over the floating gate structure. A control gate structure is formed over the oxide-nitride-oxide stack. A word line oxide layer is formed over the semiconductor substrate laterally on a first side of the floating gate structure. A word line structure is formed over the word line oxide layer. After forming the word line structure, a gate oxide layer is formed. A gate electrode is formed over the gate oxide layer.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1, 2, and 3 are cross-sectional views of respective semiconductor devices according to some examples.

FIGS. 4, 5, 6, 7, 8, 9, 10, 11, 12, 13, 14, 15, 16, 17, 18, 19, 20, 21, 22, 23, 24A, 24B, 24C, and 25 are respective cross-sectional views of a semiconductor device in intermediate stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to an integrated circuit (IC) including a flash memory bit structure. In some examples, an IC includes a flash memory bit structure and a transistor structure on a semiconductor substrate. The flash memory bit structure includes a word line structure and a first dielectric (e.g., oxide) layer disposed between the semiconductor substrate and the word line structure. In some examples in which the first dielectric layer is an oxide, the first dielectric layer may be free of nitridation. The transistor structure includes a gate structure and a gate dielectric (e.g., oxide) layer. The gate dielectric layer is over the semiconductor substrate, and the gate structure is over the gate oxide layer. In some examples, the gate dielectric layer may be an oxide that includes nitridation. Various examples described herein permit independent control of a dielectric layer of a word line structure (e.g., a word line gate), such as permitting a thickness of the dielectric independent of other dielectric layers and permitting avoiding nitridation of the dielectric layer. Further, some examples permit modular processing of a flash memory bit structure and other complementary processing (e.g., complementary metal-oxide-semiconductor (CMOS) processing). Such modular processing may permit ease of design of a process flow, such as for inserting and/or removing processing for a flash memory structure. Other benefits and advantages may also be achieved.

Various examples are described subsequently. Although the specific examples may illustrate various aspects of the above generally described features, examples may incorporate any combination of the above generally described features (which are described in more detail in examples below).

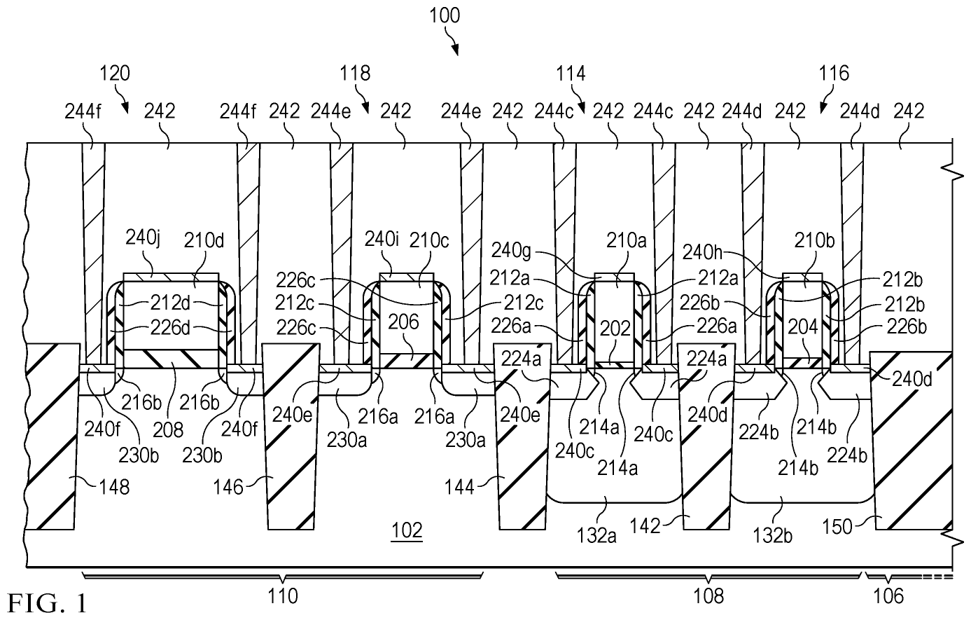

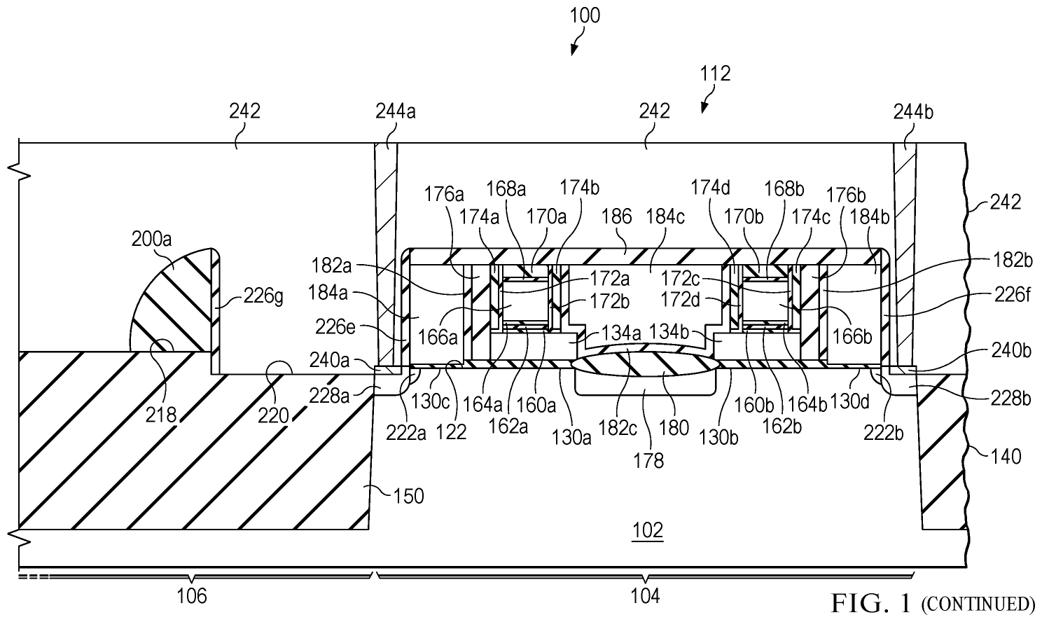

FIGS. 1, 2, and 3 are cross-sectional views of respective semiconductor devices 100, 300, 400 according to some examples. Each of the semiconductor devices 100, 300, 400 may be or may be included in an IC, such as on or in a semiconductor die or chip.

Each of the semiconductor devices 100, 300, 400 include a semiconductor substrate 102 having a flash memory region 104, a transition region 106, a p-channel FET (pFET) region 108, and an n-channel FET (nFET) region 110. The pFET region 108 and the nFET region 110 may together form a complementary FET (CFET) region (e.g., a CMOS region). Structures in the transition region 106 of the semiconductor devices 100, 300, 400 differ. Components common between the semiconductor devices 100, 300, 400 are described once for brevity.

A flash memory mirrored bit pair cell 112 is in the flash memory region 104. The flash memory mirrored bit pair cell 112 includes two flash memory bit cells that mirror each other. Although various examples are described in the context of the flash memory mirrored bit pair cell 112, other examples contemplate different numbers of flash memory bits in a cell, such as one or more flash memory bit for a cell.

The pFET region 108 includes a first pFET 114 and a second pFET 116, and the nFET region 110 includes a first nFET 118 and a second nFET 120. In the illustrated examples, an operating voltage rating of the first pFET 114 is lower than an operating voltage rating of the second pFET 116, and similarly, an operating voltage rating of the first nFET 118 is lower than an operating voltage rating of the second nFET 120. Further, the operating voltage rating of the second pFET 116 is lower than the operating voltage rating of the first nFET 118. The operating voltage ratings of the pFETs 114, 116 and nFETs 118, 120 are merely an example to illustrate how different operating voltage ratings may be achieved by examples. Any pFET and/or nFET in the pFET region 108 and the nFET region 110, respectively, may have any operating voltage rating.

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as the flash memory mirrored bit pair cell 112, pFETs 114, 116, and nFETs 118, 120, are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 122 in and/or on which devices (e.g., the flash memory mirrored bit pair cell 112, pFETs 114, 116, and nFETs 118, 120) are formed. In the illustrated example, the semiconductor material of the semiconductor substrate 102 is p-doped with a p-type dopant. In some examples, the semiconductor substrate 102 is p-doped with a p-type dopant (e.g., boron (B)) with a concentration in a range from 1×10¹⁴ cm⁻³ to 1×10¹⁵ cm⁻³. Another dopant type and/or other doping concentrations may be implemented.

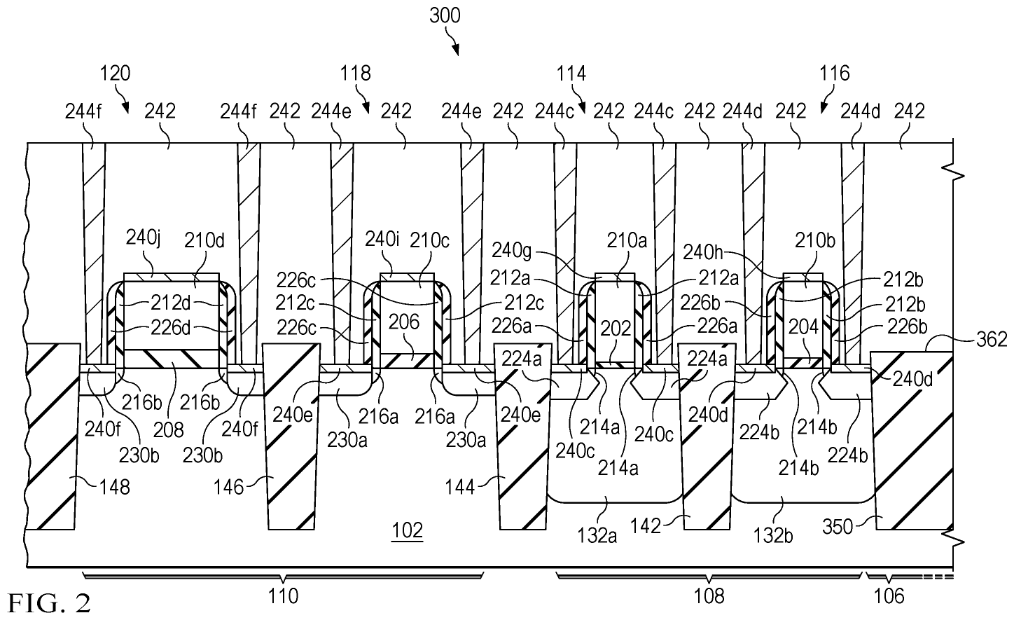

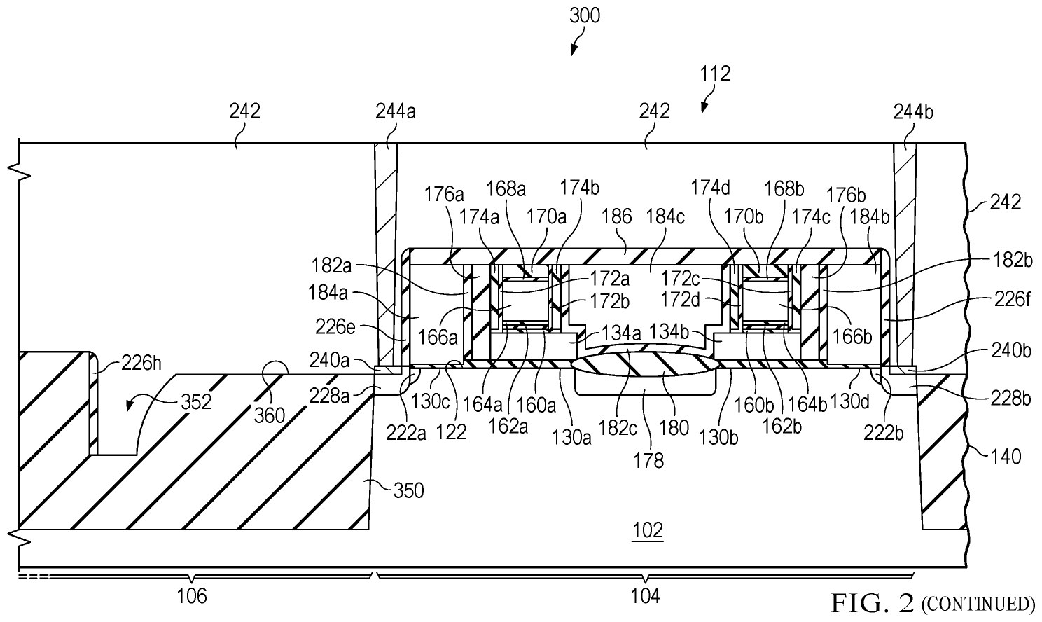

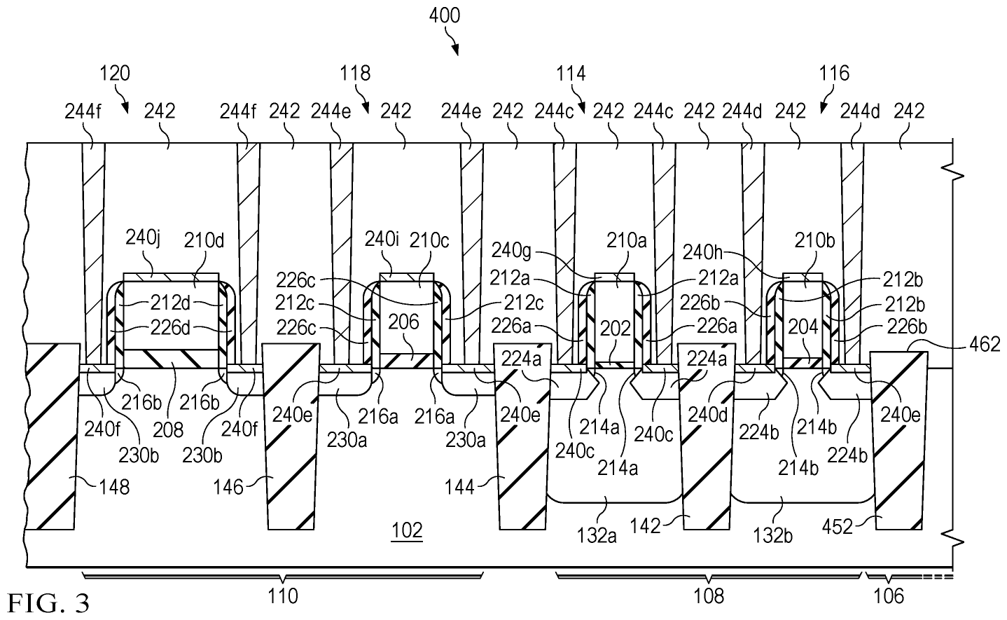

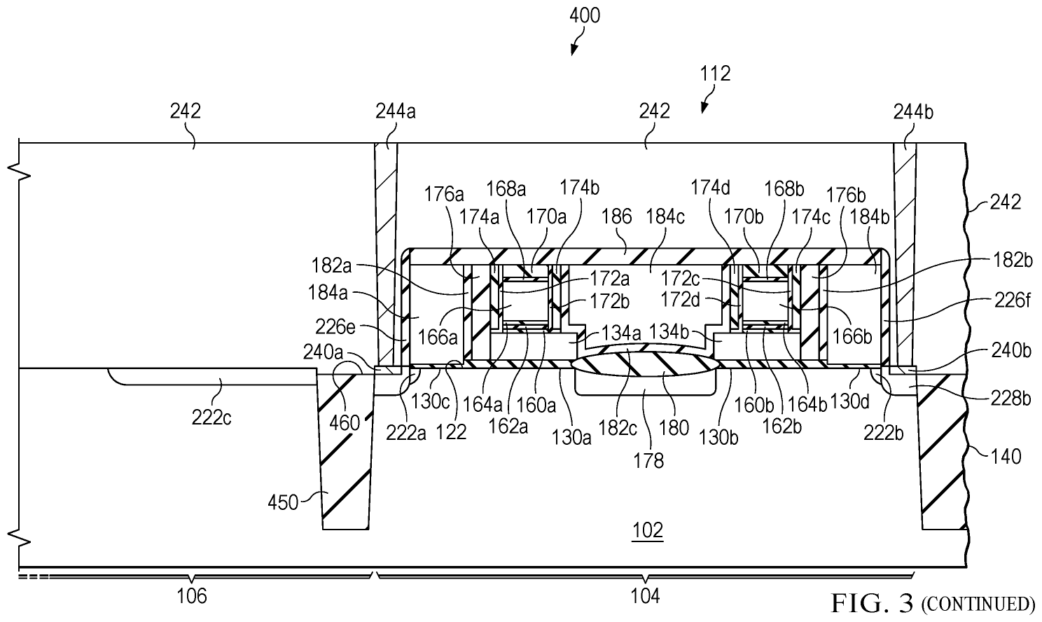

Isolation structures 140, 142, 144, 146, 148 are in the semiconductor substrate 102. Further, with respect to the semiconductor device 100 of FIG. 1, an isolation structure 150 is in the semiconductor substrate 102. With respect to the semiconductor device 300 of FIG. 2, an isolation structure 350 is in the semiconductor substrate 102. With respect to the semiconductor device 400 of FIG. 3, isolation structures 450, 452 are in the semiconductor substrate 102.

In the illustrated examples, the isolation structures 140, 142, 144, 146, 148, 150, 350, 450, 452 are shallow trench isolation structures (STIs) and/or trench oxides extending generally from the upper surface 122 of the semiconductor substrate 102 into the semiconductor substrate 102. Various isolation structures may also include a raised portion, either laterally across a whole upper surface thereof or a part thereof, above the upper surface 122 of the semiconductor substrate. For example, as illustrated, the isolation structures 142, 144, 146, 148, 150, 350, 452 are raised, either laterally in whole or in part, above the upper surface 122 of the semiconductor substrate 102. The isolation structures may have respective upper surfaces co-planar with and/or below the upper surface 122 of the semiconductor substrate 102. The isolation structures 140, 142, 144, 146, 148, 150, 350, 450, 452 may include, for example, a liner layer, such as silicon oxide or silicon nitride, conformally along surfaces of a respective trench in the semiconductor substrate 102 and a fill isolation material, such as silicon oxide, over and on the liner layer. Other isolation structures may be implemented, such as local oxidation of semiconductor (LOCOS) structures.

In the semiconductor device 100 of FIG. 1, the isolation structures 140, 150 laterally define the flash memory region 104 and an active area of the upper surface 122 of the semiconductor substrate 102 on which the flash memory mirrored bit pair cell 112 is formed. In the semiconductor device 300 of FIG. 2, the isolation structures 140, 350 laterally define the flash memory region 104 and an active area of the upper surface 122 of the semiconductor substrate 102 on which the flash memory mirrored bit pair cell 112 is formed. In the semiconductor device 400 of FIG. 3, the isolation structures 140, 450 laterally define the flash memory region 104 and an active area of the upper surface 122 of the semiconductor substrate 102 on which the flash memory mirrored bit pair cell 112 is formed.

In the semiconductor device 100 of FIG. 1, the transition region 106 is defined by lateral boundaries of the isolation structure 150. In some examples, the isolation structure 150, and hence, the transition region 106, may laterally surround or encompass the flash memory region 104 (e.g., the active area of the semiconductor substrate 102 on which the flash memory mirrored bit pair cell 112 is formed). In such situations, the isolation structure 140 may be a portion of the isolation structure 150.

In the semiconductor device 300 of FIG. 2, the transition region 106 is defined by lateral boundaries of the isolation structure 350. In some examples, the isolation structure 350, and hence, the transition region 106, may laterally surround or encompass the flash memory region 104 (e.g., the active area of the semiconductor substrate 102 on which the flash memory mirrored bit pair cell 112 is formed). In such situations, the isolation structure 140 may be a portion of the isolation structure 350.

In the semiconductor device 400 of FIG. 3, the transition region 106 is defined by lateral boundaries of the isolation structures 450, 452, where a portion of the upper surface 122 of the semiconductor substrate 102 extends between the isolation structures 450, 452 in the transition region 106. In some examples, the isolation structure 450, and hence, the transition region 106, may laterally surround or encompass the flash memory region 104 (e.g., the active area of the semiconductor substrate 102 on which the flash memory mirrored bit pair cell 112 is formed). In such situations, the isolation structure 140 may be a portion of the isolation structure 450. Further, the upper surface 122 of the semiconductor substrate 102 that extends between the isolation structures 450, 452 may likewise laterally surround or encompass the flash memory region 104.

The isolation structure 144 and respective isolation structure 150, 350, 452 laterally define the pFET region 108. The isolation structure 142, 144 laterally define an active area of the upper surface 122 of the semiconductor substrate 102 on which the first pFET 114 is formed. The isolation structure 142 and respective isolation structure 150, 350, 452 laterally define an active area of the upper surface 122 of the semiconductor substrate 102 on which the second pFET 116 is formed. N-type doped wells 132a, 132b are formed in the semiconductor substrate 102 in the pFET region 108. The n-type doped well 132a extends from the upper surface 122 of the semiconductor substrate 102 into a depth in the semiconductor substrate 102 and is laterally between the isolation structures 142, 144. The n-type doped well 132b extends from the upper surface 122 of the semiconductor substrate 102 into a depth in the semiconductor substrate 102 and is laterally between the isolation structure 142 and a respective isolation structure 150, 350, 452. A concentration of the n-type dopant of the n-type doped wells 132a, 132b is greater than a concentration of the p-type dopant of the p-type doped semiconductor substrate 102. In some examples, the n-type doped wells 132a, 132b are doped with an n-type dopant (e.g., phosphorus (P) or arsenic (As)) with a concentration in a range from 1×10¹⁵ cm⁻³ to 1×10¹⁷ cm⁻³. Another dopant type and/or other doping concentrations may be implemented.

The isolation structures 144, 148 laterally define the nFET region 110. The isolation structures 144, 146 laterally define an active area of the upper surface 122 of the semiconductor substrate 102 on which the first nFET 118 is formed. The isolation structures 146, 148 laterally define an active area of the upper surface 122 of the semiconductor substrate 102 on which the second nFET 120 is formed.

The flash memory mirrored bit pair cell 112 includes a first flash memory bit structure and a second flash memory bit structure mirrored to the first flash memory bit structure. The first flash memory bit structure includes a floating gate (FG) dielectric layer 130a over (e.g., on) the upper surface 122 of the semiconductor substrate 102. An FG electrode 134a is over the FG dielectric layer 130a. A control gate (CG) dielectric layer is over the FG electrode 134a. The CG dielectric layer includes a first dielectric sub-layer 160a over the FG electrode 134a, a second dielectric sub-layer 162a over the first dielectric sub-layer 160a, and a third dielectric sub-layer 164a over the second dielectric sub-layer 162a. In other examples, the CG dielectric layer may be or include one or more dielectric layers. A CG electrode 166a is over the CG dielectric layer (e.g., over the third dielectric sub-layer 164a). A first dielectric cap layer 168a is over the CG electrode 166a, and a second dielectric cap layer 170a is over the first dielectric cap layer 168a.

First CG dielectric spacers 172a, 172b are on or along opposing sidewalls of the CG electrode 166a and over the FG electrode 134a. The first CG dielectric spacers 172a, 172b are further on or along opposing respective sidewalls of the CG dielectric layer (e.g., the dielectric sub-layers 160a, 162a, 164a) and the dielectric cap layers 168a, 170a. Second CG dielectric spacers 174a, 174b are on or along respective sidewalls of respective first CG dielectric spacers 172a, 172b. The first CG dielectric spacer 172a is between the second CG dielectric spacer 174a and the CG electrode 166a, and the first CG dielectric spacer 172b is between the second CG dielectric spacer 174b and the CG electrode 166a.

A first word line gate (WLG) dielectric spacer 176a is on or along respective sidewalls of the CG dielectric spacers 172a, 174a and the FG electrode 134a and over the FG dielectric layer 130a. A second WLG dielectric spacer 182a is on or along a sidewall of the first WLG dielectric spacer 176a and over the FG dielectric layer 130a. The first WLG dielectric spacer 176a is between (i) the second WLG dielectric spacer 182a and (ii) the CG dielectric spacers 172a, 174a and the FG electrode 134a. A WLG dielectric layer 130c extends laterally from the FG dielectric layer 130a and is over the upper surface 122 of the semiconductor substrate 102. A WLG electrode 184a is over the WLG dielectric layer 130c and on or along a sidewall of the second WLG dielectric spacer 182a. The second WLG dielectric spacer 182a is between the WLG electrode 184a and the first WLG dielectric spacer 176a. The WLG dielectric spacers 176a, 182a and the CG dielectric spacers 172a, 174a are between the WLG electrode 184a and the CG electrode 166a. The WLG dielectric spacers 176a, 182a are between the WLG electrode 184a and the FG electrode 134a. A gate dielectric spacer 226e is on or along a sidewall of the WLG electrode 184a on a side of the WLG electrode 184a opposite from the second WLG dielectric spacer 182a.

An n-type source/drain (NSD) region 228a is in the semiconductor substrate 102 extending from the upper surface 122 into a depth in the semiconductor substrate 102. The NSD region 228a extends laterally from the WLG dielectric layer 130c opposite from the FG electrode 134a. An n-type cell lightly doped drain region (LDD) 222a is in the semiconductor substrate 102 extending from the upper surface 122 into a depth in the semiconductor substrate 102. The depth in the semiconductor substrate 102 to which the n-type cell LDD 222a extends is less than the depth in the semiconductor substrate 102 to which the NSD region 228a extends. The n-type cell LDD 222a extends laterally from the NSD region 228a under the WLG dielectric layer 130c and the WLG electrode 184a.

The second flash memory bit structure includes an FG dielectric layer 130b over (e.g., on) the upper surface 122 of the semiconductor substrate 102. An FG electrode 134b is over the FG dielectric layer 130b. A CG dielectric layer is over the FG electrode 134b. The CG dielectric layer includes a first dielectric sub-layer 160b over the FG electrode 134b, a second dielectric sub-layer 162b over the first dielectric sub-layer 160b, and a third dielectric sub-layer 164b over the second dielectric sub-layer 162b. In other examples, the CG dielectric layer may be or include one or more dielectric layers. A CG electrode 166b is over the CG dielectric layer (e.g., over the third dielectric sub-layer 164b). A first dielectric cap layer 168b is over the CG electrode 166b, and a second dielectric cap layer 170b is over the first dielectric cap layer 168b.

First CG dielectric spacers 172c, 172d are on or along opposing sidewalls of the CG electrode 166b and over the FG electrode 134b. The first CG dielectric spacers 172c, 172d are further on or along opposing respective sidewalls of the CG dielectric layer (e.g., the dielectric sub-layers 160b, 162b, 164b) and the dielectric cap layers 168b, 170b. Second CG dielectric spacers 174c, 174d are on or along respective sidewalls of respective first CG dielectric spacers 172c, 172d. The first CG dielectric spacer 172c is between the second CG dielectric spacer 174c and the CG electrode 166b, and the first CG dielectric spacer 172d is between the second CG dielectric spacer 174d and the CG electrode 166b.

A first WLG dielectric spacer 176b is on or along respective sidewalls of the CG dielectric spacers 172c, 174c and the FG electrode 134b and over the FG dielectric layer 130b. A second WLG dielectric spacer 182b is on or along a sidewall of the first WLG dielectric spacer 176b and over the FG dielectric layer 130b. The first WLG dielectric spacer 176b is between (i) the second WLG dielectric spacer 182b and (ii) the CG dielectric spacers 172c, 174c and the FG electrode 134b. A WLG dielectric layer 130d extends laterally from the FG dielectric layer 130b and is over the upper surface 122 of the semiconductor substrate 102. A WLG electrode 184b is over the WLG dielectric layer 130d and on or along a sidewall of the second WLG dielectric spacer 182b. The second WLG dielectric spacer 182b is between the WLG electrode 184b and the first WLG dielectric spacer 176b. The WLG dielectric spacers 176b, 182b and the CG dielectric spacers 172c, 174c are between the WLG electrode 184b and the CG electrode 166b. The WLG dielectric spacers 176b, 182b are between the WLG electrode 184b and the FG electrode 134b. A gate dielectric spacer 226f is on or along a sidewall of the WLG electrode 184b on a side of the WLG electrode 184b opposite from the second WLG dielectric spacer 182b.

An NSD region 228b is in the semiconductor substrate 102 extending from the upper surface 122 into a depth in the semiconductor substrate 102. The NSD region 228b extends laterally from the WLG dielectric layer 130d opposite from the FG electrode 134b. An n-type cell LDD 222b is in the semiconductor substrate 102 extending from the upper surface 122 into a depth in the semiconductor substrate 102. The depth in the semiconductor substrate 102 to which the n-type cell LDD 222b extends is less than the depth in the semiconductor substrate 102 to which the NSD region 228b extends. The n-type cell LDD 222b extends laterally from the NSD region 228b under the WLG dielectric layer 130d and the WLG electrode 184b.

The first flash memory bit structure and the second flash memory bit structure include an isolation structure 180 at the upper surface 122 of the semiconductor substrate 102. The isolation structure 180 is laterally between the FG dielectric layers 130a, 130b. A shared NSD region 178 is in the semiconductor substrate 102 extending from the upper surface 122 into a depth in the semiconductor substrate 102. The shared NSD region 178 underlies the isolation structure 180. A tunnel dielectric layer 182c is on and along sidewalls of the CG dielectric spacers 174b, 174d, 172b, 172d, over the FG electrodes 134a, 134b, on and along sidewalls of the FG electrodes 134a, 134b, and over the isolation structure 180. A shared erase gate (EG) electrode 184c is over the tunnel dielectric layer 182c. A protective dielectric layer 186 is over the WLG electrodes 184a, 184b, the shared EG electrode 184c, and second dielectric cap layers 170a, 170b, among others.

The FG electrodes 134a, 134b may be any material that is capable of trapping electrons. In some examples, the FG electrodes 134a, 134b are or include a semiconductor material, such as doped polysilicon. In examples in which the FG electrodes 134a, 134b include a doped semiconductor material (e.g., polysilicon), the FG electrodes 134a, 134b may be doped with an n-type dopant with a concentration in a range from 1×10¹⁹ cm⁻³ to 1×10²¹ cm⁻³, The CG electrodes 166a, 166b, WLG electrodes 184a, 184b, and shared EG electrode 184c may be or include any conductive material, such as a doped semiconductor material, like doped polysilicon. In examples in which the CG electrodes 166a, 166b, WLG electrodes 184a, 184b, and shared EG electrode 184c include a doped semiconductor material (e.g., polysilicon), the CG electrodes 166a, 166b may be doped with an n-type dopant with a concentration in a range from 1×10¹⁹ cm⁻³ to 1×10²¹ cm⁻³, and the WLG electrodes 184a, 184b and shared EG electrode 184c may be doped with an n-type dopant with a concentration in a range from 5×10¹⁹ cm⁻³ to 5×10²¹ cm⁻³. Another dopant type and/or other doping concentrations may be implemented.

The FG dielectric layers 130a, 130b, WLG dielectric layers 130c, 130d, and CG dielectric layers (e.g., including dielectric sub-layers 160a, 160b, 162a, 162b, 164a, 164b) may be or include any appropriate dielectric material. In some examples, FG dielectric layers 130a, 130b and WLG dielectric layers 130c, 130d are each an oxide, such as silicon oxide. Further, in some examples, the WLG dielectric layers 130c, 130d are each an oxide (e.g., silicon oxide) that is free of nitridation. As illustrated subsequently, the WLG dielectric layers 130c, 130d may be formed (e.g., by oxidation and/or deposition) free of nitridation, and the WLG dielectric layers 130c, 130d may be masked during and/or protected from any nitridation process subsequent to the formation of the WLG dielectric layers 130c, 130d. In some examples, the CG dielectric layers each are or include an oxide-nitride-oxide stack. For example, the first dielectric sub-layers 160a, 160b are each an oxide, such as silicon oxide; the second dielectric sub-layers 162a, 162b are each a nitride, such as silicon nitride; and the third dielectric sub-layers 164a, 164b are each an oxide, such as silicon oxide.

The first dielectric cap layers 168a, 168b, second dielectric cap layers 170a, 170b, and protective dielectric layer 186 may be or include any appropriate dielectric material. In some examples, the first dielectric cap layers 168a, 168b each are or include an oxide, such as silicon oxide. In some examples, the second dielectric cap layers 170a, 170b each are or include a nitride, such as silicon nitride. In some examples, the protective dielectric layer 186 is or includes a nitride, such as silicon nitride.

The CG dielectric spacers 172a-172d, 174a-174d and WLG dielectric spacers 176a, 176b, 182a, 182b may be any appropriate dielectric material. In some examples, the first CG dielectric spacers 172a-172d and WLG dielectric spacers 176a, 176b, 182a, 182b are or include an oxide, such as silicon oxide, and the second CG dielectric spacers 174a-174d are or include a nitride, such as silicon nitride.

The isolation structure 180 and tunnel dielectric layer 182c may be or include any appropriate dielectric material. In some examples, the isolation structure 180 and tunnel dielectric layer 182c each are or include an oxide, such as silicon oxide. For example, the isolation structure 180 may be or include a LOCOS structure, which is oxidized semiconductor material (e.g., silicon) of the semiconductor substrate 102. In some examples, the tunnel dielectric layer 182c is an oxide (e.g., silicon oxide) that is free of nitridation. As illustrated subsequently, the tunnel dielectric layer 182c may be formed (e.g., by deposition) free of nitridation, and the tunnel dielectric layer 182c may be masked during and/or protected from any nitridation process subsequent to the formation of the tunnel dielectric layer 182c. Likewise, in some examples, the second WLG dielectric spacers 182a, 182b each are an oxide (e.g., silicon oxide) that is free of nitridation. As illustrated subsequently, the second WLG dielectric spacers 182a, 182b may be formed free of nitridation, and the second WLG dielectric spacers 182a, 182b may be masked during and/or protected from any nitridation process subsequent to the formation of the tunnel dielectric layer 182c.

The n-type cell LDDs 222a, 222b may be doped with an n-type dopant. Concentrations of the n-type dopant of the n-type cell LDDs 222a, 222b are greater than a concentration of the p-type dopant of the p-type doped semiconductor substrate 102. In some examples, the n-type cell LDDs 222a, 222b are doped with an n-type dopant with a concentration in a range from 5×10¹⁹ cm⁻³ to 5×10²¹ cm⁻³. Another dopant type and/or other doping concentrations may be implemented.

The shared NSD region 178 and NSD regions 228a, 228b may be doped with an n-type dopant. Concentrations of the n-type dopant of the shared NSD region 178 and NSD regions 228a, 228b are greater than respective concentrations of the n-type dopant of the n-type cell LDDs 222a, 222b and a concentration of the p-type dopant of the p-type doped semiconductor substrate 102. In some examples, the shared NSD region 178 is doped with an n-type dopant with a concentration in a range from 5×10¹⁹ cm⁻³ to 5×10²¹ cm⁻³. In some examples, the NSD regions 228a, 228b are doped with an n-type dopant with a concentration in a range from 5×10¹⁹ cm⁻³ to 5×10²¹ cm⁻³. Another dopant type and/or other doping concentrations may be implemented.

The first pFET 114 includes a gate electrode 210a and p-type source/drain (PSD) regions in the semiconductor substrate 102 on laterally opposing sides of the gate electrode 210a. Embedded stressors 224a are also in the semiconductor substrate 102 on laterally opposing sides of the gate electrode 210a, and the PSD regions may be at least partially in respective embedded stressors 224a. The embedded stressors 224a and PSD regions are in the n-type doped well 132a in the semiconductor substrate 102. The PSD regions extend from respective upper surfaces of the embedded stressors 224a into a depth in the embedded stressors 224a and/or the semiconductor substrate 102. The upper surfaces of the embedded stressors 224a may be at, above, or below the upper surface 122 of the semiconductor substrate. A gate dielectric layer 202 is over the upper surface 122 of the semiconductor substrate 102, and the gate electrode 210a is over the gate dielectric layer 202. A channel region is in the semiconductor substrate 102 underlying the gate dielectric layer 202 and gate electrode 210a. The channel region is between the PSD regions and between the embedded stressors 224a. P-type LDDs 214a are in the semiconductor substrate 102 on laterally opposing sides of the gate electrode 210a. Each p-type LDD 214a is between the channel region and a respective PSD region. First gate dielectric spacers 212a are on respective opposing sidewalls of the gate electrode 210a, and second gate dielectric spacers 226a are on respective sidewalls of the first gate dielectric spacers 212a.

Similarly, the second pFET 116 includes a gate electrode 210b and PSD regions in the semiconductor substrate 102 on laterally opposing sides of the gate electrode 210b. Embedded stressors 224b are also in the semiconductor substrate 102 on laterally opposing sides of the gate electrode 210b, and the PSD regions may be at least partially in respective embedded stressors 224b. The embedded stressors 224b and PSD regions are in the n-type doped well 132b in the semiconductor substrate 102. The PSD regions extend from respective upper surfaces of the embedded stressors 224b into a depth in the embedded stressors 224b and/or the semiconductor substrate 102. The upper surfaces of the embedded stressors 224b may be at, above, or below the upper surface 122 of the semiconductor substrate. A gate dielectric layer 204 is over the upper surface 122 of the semiconductor substrate 102, and the gate electrode 210b is over the gate dielectric layer 204. A channel region is in the semiconductor substrate 102 underlying the gate dielectric layer 204 and gate electrode 210b. The channel region is between the PSD regions and between the embedded stressors 224b. P-type LDDs 214b are in the semiconductor substrate 102 on laterally opposing sides of the gate electrode 210a. Each p-type LDD 214b is between the channel region and a respective PSD region. First gate dielectric spacers 212b are on respective opposing sidewalls of the gate electrode 210b, and second gate dielectric spacers 226b are on respective sidewalls of the first gate dielectric spacers 212b.

The first nFET 118 includes a gate electrode 210c and NSD regions 230a in the semiconductor substrate 102 on laterally opposing sides of the gate electrode 210c. The NSD regions 230a extend from the upper surface 122 of the semiconductor substrate 102 into a depth in the semiconductor substrate 102. A gate dielectric layer 206 is over the upper surface 122 of the semiconductor substrate 102, and the gate electrode 210c is over the gate dielectric layer 206. A channel region is in the semiconductor substrate 102 underlying the gate dielectric layer 206 and gate electrode 210c. The channel region is between the NSD regions 230a. N-type LDDs 216a are in the semiconductor substrate 102 on laterally opposing sides of the gate electrode 210c. Each n-type LDD 216a is between the channel region and a respective NSD region 230a. First gate dielectric spacers 212c are on respective opposing sidewalls of the gate electrode 210c, and second gate dielectric spacers 226c are on respective sidewalls of the first gate dielectric spacers 212c.

Similarly, the second nFET 120 includes a gate electrode 210d and NSD regions 230b in the semiconductor substrate 102 on laterally opposing sides of the gate electrode 210d. The NSD regions 230b extend from the upper surface 122 of the semiconductor substrate 102 into a depth in the semiconductor substrate 102. A gate dielectric layer 208 is over the upper surface 122 of the semiconductor substrate 102, and the gate electrode 210d is over the gate dielectric layer 208. A channel region is in the semiconductor substrate 102 underlying the gate dielectric layer 208 and gate electrode 210d. The channel region is between the NSD regions 230b. N-type LDDs 216b are in the semiconductor substrate 102 on laterally opposing sides of the gate electrode 210d. Each n-type LDD 216b is between the channel region and a respective NSD region 230b. First gate dielectric spacers 212d are on respective opposing sidewalls of the gate electrode 210d, and second gate dielectric spacers 226d are on respective sidewalls of the first gate dielectric spacers 212d.

The p-type LDDs 214a, 214b may be doped with a p-type dopant. Concentrations of the p-type dopant of the p-type LDDs 214a, 214b are greater than concentrations of the n-type dopant of the n-type doped wells 132a, 132b, respectively, and a concentration of the p-type dopant of the p-type doped semiconductor substrate 102. In some examples, the p-type LDDs 214a, 214b are doped with a p-type dopant with a concentration in a range from 5×10¹⁹ cm⁻³ to 5×10²¹ cm⁻³. The n-type LDDs 216a, 216b may be doped with an n-type dopant. Concentrations of the n-type dopant of the n-type LDDs 216a, 216b are greater than a concentration of the p-type dopant of the p-type doped semiconductor substrate 102. In some examples, the n-type LDDs 216a, 216b are doped with an n-type dopant with a concentration in a range from 5×10¹⁹ cm⁻³ to 5×10²¹ cm⁻³. Other doping concentrations may be implemented.

The PSD regions may be doped with a p-type dopant. Concentrations of the p-type dopant of the PSD regions are greater than concentrations of the p-type dopant of the p-type LDDs 214a, 214b and concentrations of the n-type dopant of the n-type doped wells 132a, 132b, respectively. In some examples, the PSD regions are doped with a p-type dopant with a concentration in a range from 5×10¹⁹ cm⁻³ to 5×10²¹ cm⁻³. The NSD regions 230a, 230b may be doped with an n-type dopant. Concentrations of the n-type dopant of the NSD regions 230a, 230b are greater than respective concentrations of the n-type dopant of the n-type LDDs 216a, 216b and a concentration of the p-type dopant of the p-type doped semiconductor substrate 102. In some examples, the NSD regions 230a, 230b are doped with an n-type dopant with a concentration in a range from 5×10¹⁹ cm⁻³ to 5×10²¹ cm⁻³. Other doping concentrations may be implemented.

The embedded stressors 224a, 224b may be or include any appropriate semiconductor material that applies an appropriate stress to the respective channel region of the pFET 114, 116. In some examples, the embedded stressors 224a, 224b apply a compressive stress to the respective channel region. When the semiconductor material of the semiconductor substrate 102 is silicon, the embedded stressors 224a, 224b may be silicon germanium (SiGe), for example. In other examples, embedded stressors may be implemented in an nFET and may apply a tensile stress to the channel region of the nFET. In such an example, and when the semiconductor material of the semiconductor substrate 102 is silicon, the embedded stressors may be silicon carbide (SiC), for example.

The gate dielectric layers 202, 204, 206, 208 may be or include any appropriate dielectric material. In some examples, the gate dielectric layers 202-208 include an oxide, such as silicon oxide. Further, in some examples, the gate dielectric layers 202-208 include a nitrided oxide, such as nitrided silicon oxide. For example, as described subsequently, silicon oxide may be formed for the gate dielectric layers 202-208 using an oxidation process, and the silicon oxide may then undergo a nitridation process to nitride the silicon oxide. The formation of the gate dielectric layers 202-208 may be subsequent to the formation of the WLG dielectric layers 130c, 130d, the tunnel dielectric layer 182c, and second WLG dielectric spacers 182a, 182b; however, the WLG dielectric layers 130c, 130d, the tunnel dielectric layer 182c, and second WLG dielectric spacers 182a, 182b are masked and/or protected from the nitridation of the gate dielectric layers 202-208. The gate dielectric layer 204 is thicker than the gate dielectric layer 202. The gate dielectric layer 206 is thicker than the gate dielectric layer 204. The gate dielectric layer 208 is thicker than the gate dielectric layer 206. The respective thicknesses of the gate dielectric layers 202-208 may, at least in part, achieve the operating voltage ratings as described previously.

The gate electrodes 210a, 210b, 210c, 210d may be or include any appropriate conductive material, such as a doped semiconductor material, like doped polysilicon. In examples in which the gate electrodes 210a, 210b include a doped semiconductor material (e.g., polysilicon), the gate electrodes 210a, 210b may be doped with a p-type dopant with a concentration in a range from 5×10¹⁹ cm⁻³ to 5×10²¹ cm⁻³. In examples in which the gate electrodes 210c, 210d include a doped semiconductor material (e.g., polysilicon), the gate electrodes 210c, 210d may be doped with an n-type dopant with a concentration in a range from 5×10¹⁹ cm⁻³ to 5×10²¹ cm⁻³. Another dopant type and/or other doping concentrations may be implemented.

The first gate dielectric spacers 212a, 212b, 212c, 212d, second gate dielectric spacers 226a, 226b, 226c, 226d, and gate dielectric spacers 226e, 226f may be or include any appropriate dielectric material. For example, the gate dielectric spacers 212a-212d, 226a-226f may be or include silicon oxide, silicon nitride, silicon oxynitride, silicon carbon nitride, the like or a combination thereof.

Referring specifically to FIG. 1, a protective dielectric 200a is over the isolation structure 150 in the transition region 106. The protective dielectric 200a is a protrusion protruding vertically from an upper surface 218 of the isolation structure 150. The protective dielectric 200a has a sidewall facing the flash memory region 104 on which a residual dielectric spacer 226g is formed. The protective dielectric 200a (and possibly, the residual dielectric spacer 226g) may form a fence extending laterally in a direction perpendicular to the cross-section of FIG. 1 along the flash memory region 104. As described in detail subsequently, the protective dielectric 200a may result from misalignment of photoresists during processing. Further, an upper surface 220 of the isolation structure 150 on a lateral side of the protective dielectric 200a proximate the flash memory region 104, as illustrated, is below a level of the upper surface 122 of the semiconductor substrate 102 in the flash memory region 104. The upper surface 218 of the isolation structure 150 underlies the protective dielectric 200a and extends laterally from the protective dielectric 200a away from the flash memory region 104. The upper surface 218 is at a level above the upper surface 220. The upper surface 218 may be above, at, or below a level of the upper surface 122 of the semiconductor substrate 102. The residual dielectric spacer 226g may be or include a same material as the second gate dielectric spacers 226a-226d.

Referring specifically to FIG. 2, a recess 352 is in the isolation structure 350 in the transition region 106. The recess 352 has a sidewall facing the flash memory region 104 on which a residual dielectric spacer 226h is formed. The recess 352 (and possibly, the residual dielectric spacer 226h) may extend laterally in a direction perpendicular to the cross-section of FIG. 2 along the flash memory region 104. As described in detail subsequently, the recess 352 may result from misalignment of photoresists during processing. Further, an upper surface 360 of the isolation structure 350 on a lateral side of the recess 352 proximate the flash memory region 104, as illustrated, is below a level of the upper surface 122 of the semiconductor substrate 102 in the flash memory region 104. An upper surface 362 of the isolation structure 350 extends laterally from the recess 352 away from the flash memory region 104. The upper surface 362 is at a level above the upper surface 360. The upper surface 362 may be above, at, or below a level of the upper surface 122 of the semiconductor substrate 102. The residual dielectric spacer 226h may be or include a same material as the second gate dielectric spacers 226a-226d.

Referring specifically to FIG. 3, the upper surface 122 of the semiconductor substrate 102 is between the isolation structures 450, 452 in the transition region 106. As described in detail subsequently, with some misalignments of photoresists during processing, the semiconductor substrate 102 may act as an etch stop such that a recess is not formed in the semiconductor substrate 102 in the transition region 106. With some misalignments, a protrusion may be formed over the semiconductor substrate 102 in the transition region 106, like the protective dielectric 200a as shown in FIG. 1. Further, an upper surface 460 of the isolation structure 450, as illustrated, is below a level of the upper surface 122 of the semiconductor substrate 102 in the flash memory region 104. An upper surface 462 of the isolation structure 452 is at a level above the upper surface 460. The upper surface 462 may be above, at, or below a level of the upper surface 122 of the semiconductor substrate 102. As illustrated, a residual n-type cell LDD 222c is in the semiconductor substrate 102 extending from the upper surface 122 into a depth in the semiconductor substrate 102 and between the isolation structures 450, 452 in the transition region 106. The residual n-type cell LDD 222c extends laterally from the isolation structure 450 away from the isolation structure 450.

Various aspects of the transition region 106 of FIGS. 1, 2, and 3 may be implemented and combined in a semiconductor device. For example, for a given flash memory region having a first transition region on a first lateral side and a second transition region on an opposite, second lateral side, the first and second transition regions may both include a protective dielectric 200a (e.g., if photoresists overlap on both of the opposing sides, as detailed subsequently). Further, in some examples, the first and second transition regions may both have a recess 352 (e.g., if photoresists have a gap on both of the opposing sides, as detailed subsequently). Also, in some examples, the first transition region may include a protective dielectric 200a, while the second transition region may have a recess (e.g., if photoresists are laterally offset resulting in an overlap on one side and a gap on another).

Referring collectively to FIGS. 1, 2, and 3, a metal-semiconductor compound 240a is on the upper surface 122 of the semiconductor substrate 102 and on the NSD region 228a. A metal-semiconductor compound 240b is on the upper surface 122 of the semiconductor substrate 102 and on the NSD region 228b. Metal-semiconductor compound 240c are on embedded stressors 224a. Metal-semiconductor compound 240d are on embedded stressors 224b. Metal-semiconductor compound 240e are on the upper surface 122 of the semiconductor substrate 102 and on the NSD regions 230a. Metal-semiconductor compound 240f are on the upper surface 122 of the semiconductor substrate 102 and on the NSD regions 230b. Metal-semiconductor compound 240g, 240h, 240i, 240j are on the gate electrodes 210a, 210b, 210c, 210d, respectively. The metal-semiconductor compound 240a-240j may be a silicide (e.g., NiSix, TiSix, CoSix, PtSix), a germanicide, or the like.

A dielectric layer 242 is over the semiconductor substrate 102 (e.g., over the flash memory mirrored bit pair cell 112, pFETs 114, 116, and nFETs 118, 120), and contacts 244a, 244b, 244c, 244d, 244e, 244f are through the dielectric layer 242. The dielectric layer 242 may include one or more dielectric sub-layers. For example, the dielectric layer 242 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 242 may be or include a pre-metal dielectric (PMD), an inter-layer dielectric (ILD), or the like.

The contacts 244a, 244b, 244c, 244d, 244e, 244f extend through the dielectric layer 242 and contact respective metal-semiconductor compound 240a, 240b, 240c, 240d, 240e, 240f. The contacts 244a-244f may each include one or more barrier and/or adhesion layers (e.g., titanium nitride (TiN), tantalum nitride (TaN), the like, or a combination thereof) conformally in a respective opening through the dielectric layer 242, and a fill metal (e.g., tungsten (W), copper (Cu), aluminum (Al), the like, or a combination thereof) over and/or on the barrier and/or adhesion layer(s).

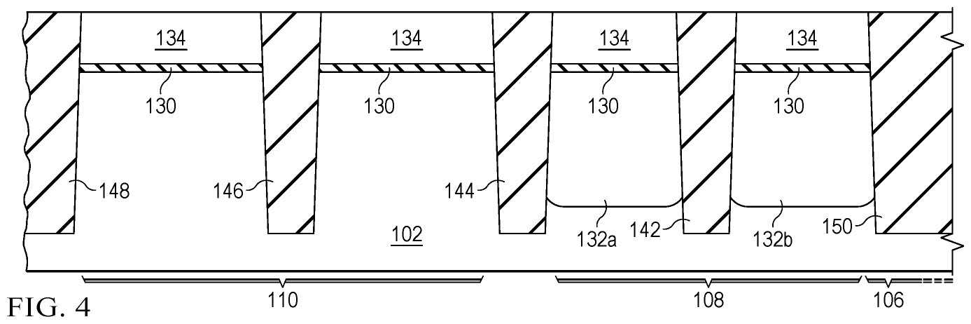

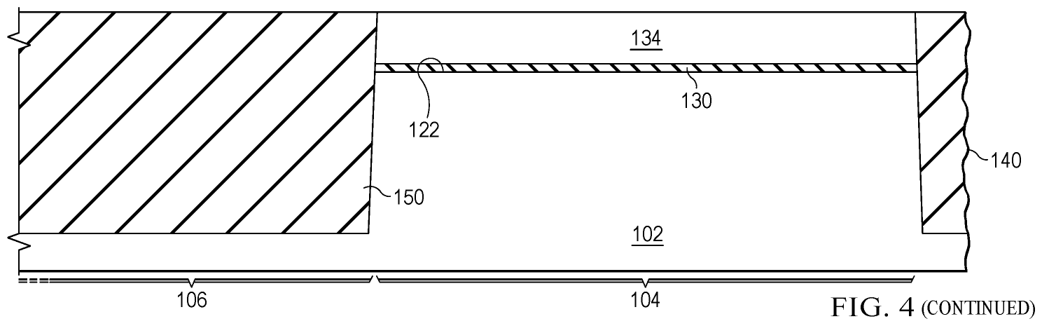

FIGS. 4 through 23, 24A, 24B, 24C, and 25 are respective cross-sectional views of a semiconductor device in intermediate stages of manufacturing according to some examples. The processing described with respect to these figures is generally in the context of the semiconductor device 100 of FIG. 1. The same processing may be implemented to manufacture the semiconductor devices 300, 400 of FIGS. 2 and 3, except that misalignment of photoresists and/or different isolation structures may occur and/or be implemented, as described below.

Referring to FIG. 4, a semiconductor substrate 102 is provided. The semiconductor substrate 102 may be as described above. A gate dielectric layer 130 is formed over (e.g., on) the upper surface 122 of the semiconductor substrate. The gate dielectric layer 130 may be any material described above with respect to the FG dielectric layer 130a, 130b and WLG dielectric layer 130c, 130d. The gate dielectric layer 130 may be formed using an oxidation process, such as in situ steam generation (ISSG) oxidation, or another deposition process, such as chemical vapor deposition (CVD) or the like. In some examples, such as when the gate dielectric layer 130 is an oxide (e.g., silicon oxide), no nitridation of the gate dielectric layer 130 is performed to form the gate dielectric layer 130.

N-type doped wells 132a, 132b are formed in the semiconductor substrate 102 in the pFET region 108. The n-type doped wells 132a, 132b may be formed by masking (e.g., by a photoresist using photolithography) areas of the semiconductor substrate 102 where an n-type doped well is not to be formed and implanting n-type dopants into the semiconductor substrate 102. Concentrations of the n-type dopant of the n-type doped wells 132a, 132b may be as described above.

An FG electrode layer 134 is formed over the gate dielectric layer 130. The FG electrode layer 134 may be any material described above with respect to the FG electrodes 134a, 134b. The FG electrode layer 134 may be formed using any appropriate deposition process, such as CVD, plasma enhanced CVD (PECVD), or the like. The FG electrode layer 134 may be doped (e.g., by in situ doping during deposition and/or implantation subsequent to deposition) to a concentration described above with respect to the FG electrodes 134a, 134b.

Isolation structures 140-148 and isolation structure 150 (or isolation structure 350 or isolation structures 450, 452, depending on which semiconductor device of FIGS. 1, 2, and 3 is to be manufactured) are formed in the semiconductor substrate 102. The isolation structures 140-150, as illustrated, may be formed by depositing a hardmask layer over the FG electrode layer 134. The hardmask layer may be any appropriate material, such as silicon nitride, silicon oxynitride, or the like, and may be deposited using any appropriate deposition process, such as CVD. The hardmask layer is patterned, such as by using photolithography and an etching process (e.g., reactive ion etch (RIE)). Trenches (or more generally, recesses) are etched, such as by RIE, through the FG electrode layer 134 and gate dielectric layer 130 and in the semiconductor substrate 102 using the patterned hardmask layer as a mask. A liner layer may then be conformally deposited in the trenches and over the patterned hardmask layer, such as by PECVD or atomic layer deposition (ALD), or formed on exposed surfaces of the trenches (e.g., by an oxidation process). A fill isolation material may be deposited over the liner layer, such as by high aspect ratio CVD (HAR-CVD), flowable CVD (FCVD), or the like. Excess fill isolation material and liner layer and the hardmask layer may be removed by a planarization process, such as a chemical mechanical polish (CMP). In other examples, the isolation structures 140-150 may be field oxide structures, such as LOCOS structures, at the upper surface 122 of the semiconductor substrate 102, which may be formed using a LOCOS process.

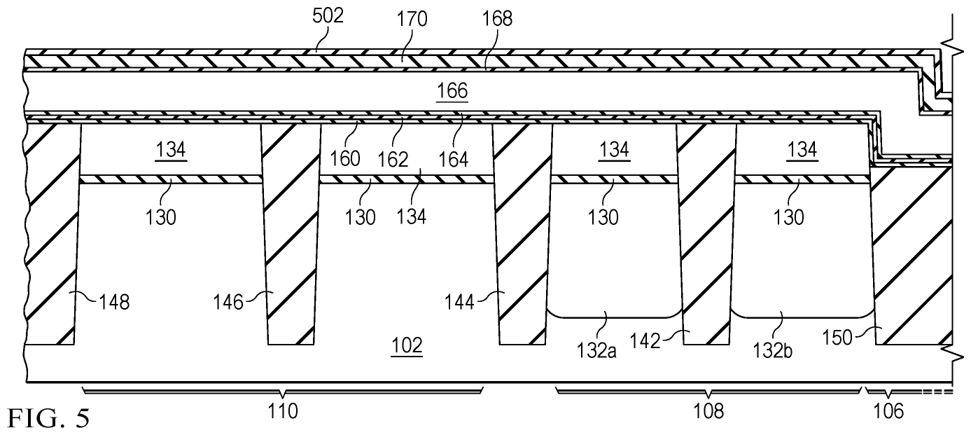

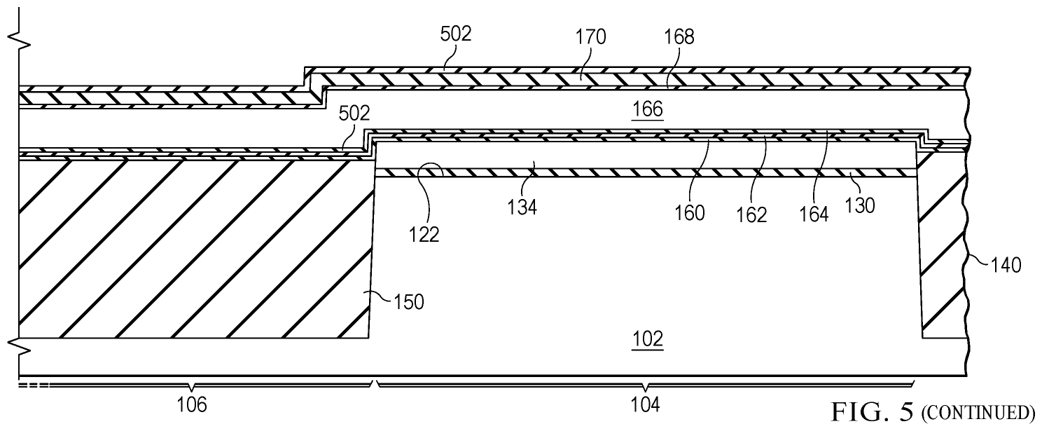

Referring to FIG. 5, the FG electrode layer 134 in the flash memory region 104 is thinned. Thinning the FG electrode layer 134 may be performed using photolithography and an etching process. For examples, the pFET region 108 and nFET region 110 may be masked (e.g., by a photoresist using photolithography), and with the pFET region 108 and nFET region 110 masked, the FG electrode layer 134 may be thinned by an etch process, which may include a wet etch and/or a dry etch. The etch process may etch any exposed isolation structures, such as the isolation structures 140, 150, as illustrated.

A CG dielectric layer is formed over the FG electrode layer 134 and isolation structures 140-150. As illustrated, the CG dielectric layer includes a first dielectric sub-layer 160 over the FG electrode layer 134, a second dielectric sub-layer 162 over the first dielectric sub-layer 160, and a third dielectric sub-layer 164 over the second dielectric sub-layer 162. As illustrated, the CG dielectric layer is formed conformally over the FG electrode layer 134 and isolation structures 140-150. For example, the CG dielectric layer is formed along sidewalls of the FG electrode layer 134 where, e.g., any isolation structures (e.g., isolation structures 140, 150) are recessed. The CG dielectric layer (e.g., dielectric sub-layers 160, 162, 164) may be any material described above with respect to the CG dielectric layer (e.g., including dielectric sub-layers 160, 162, 164). The CG dielectric layer (e.g., dielectric sub-layers 160, 162, 164) may be formed using any appropriate deposition process, such as CVD, low pressure CVD (LPCVD), PECVD, or the like.

A CG electrode layer 166 is formed over the CG dielectric layer (e.g., over the third dielectric sub-layer 164). A first dielectric cap layer 168 is formed over the CG electrode layer 166, and a second dielectric cap layer 170 is formed over the first dielectric cap layer 168. A dielectric cap buffer layer 502 is formed over the second dielectric cap layer 170. The CG electrode layer 166 may be any material described above with respect to the CG electrodes 166a, 166b. The first dielectric cap layer 168 may be any material described above with respect to the first dielectric cap layers 168a, 168b. The second dielectric cap layer 170 may be any material described above with respect to the second dielectric cap layers 170a, 170b. The dielectric cap buffer layer 502 may be any appropriate dielectric material. In some examples, the dielectric cap buffer layer 502 is or includes an oxide, such as silicon oxide. The CG electrode layer 166, first dielectric cap layer 168, second dielectric cap layer 170, and dielectric cap buffer layer 502 may be formed using any appropriate deposition process, such as CVD, LPCVD, PECVD, or the like.

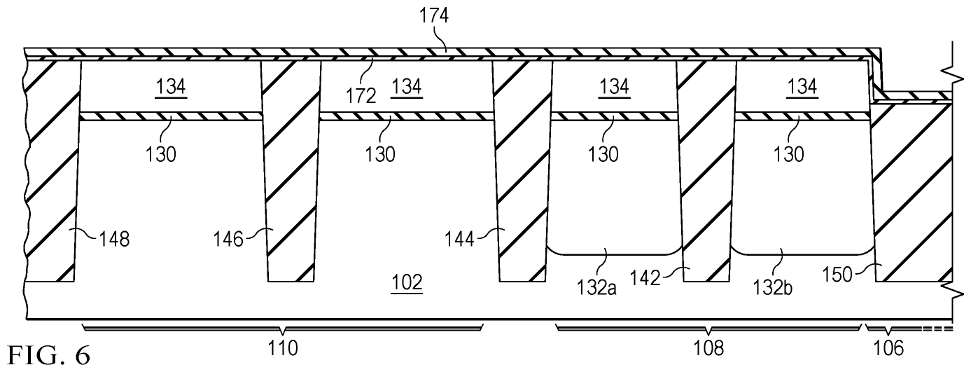

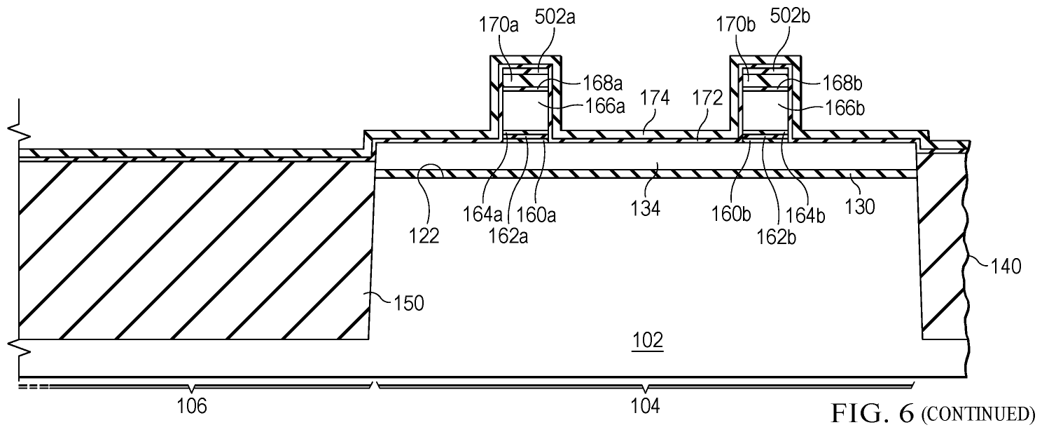

Referring to FIG. 6, the CG electrode layer 166 is patterned into CG electrodes 166a, 166b. Further, the dielectric cap buffer layer 502, second dielectric cap layer 170, first dielectric cap layer 168, and CG dielectric layer (e.g., dielectric sub-layers 160-164) are patterned. The layers may be patterned by using photolithography and an etching process (e.g., an RIE). The CG dielectric layer (e.g., dielectric sub-layers 160, 162, 164) is patterned into respective CG dielectric layers (e.g., dielectric sub-layers 160a, 162a, 164a and dielectric sub-layers 160b, 162b, 164b) with the respective CG electrodes 166a, 166b thereover. The first dielectric cap layer 168 is patterned into first dielectric cap layers 168a, 168b over the respective CG electrodes 166a, 166b, and the second dielectric cap layer 170 is patterned into second dielectric cap layers 170a, 170b over the respective first dielectric cap layers 168a, 168b. The dielectric cap buffer layer 502 is patterned into dielectric cap buffer layers 502a, 502b over the respective second dielectric cap layers 170a, 170b.

A first CG dielectric spacer layer 172 is formed over the semiconductor substrate 102, and a second CG dielectric spacer layer 174 is formed over the first CG dielectric spacer layer 172. The first CG dielectric spacer layer 172 is conformally formed over the FG electrode layer 134, isolation structures 140-150, and the dielectric cap buffer layers 502a, 502b and on and along sidewalls of the CG electrodes 166a, 166b, CG dielectric layer (e.g., dielectric sub-layers 160a-164a, 160b-164b), first dielectric cap layers 168a, 168b, second dielectric cap layers 170a, 170b, and dielectric cap buffer layers 502a, 502b. The second CG dielectric spacer layer 174 is conformally formed over the first CG dielectric spacer layer 172. The first CG dielectric spacer layer 172 may be any material described above with respect to the first CG dielectric spacers 172a-172d. The second CG dielectric spacer layer 174 may be any material described above with respect to the second CG dielectric spacers 174a-174d. The first CG dielectric spacer layer 172 and second CG dielectric spacer layer 174 may be formed using any appropriate deposition process, such as CVD, LPCVD, PECVD, or the like.

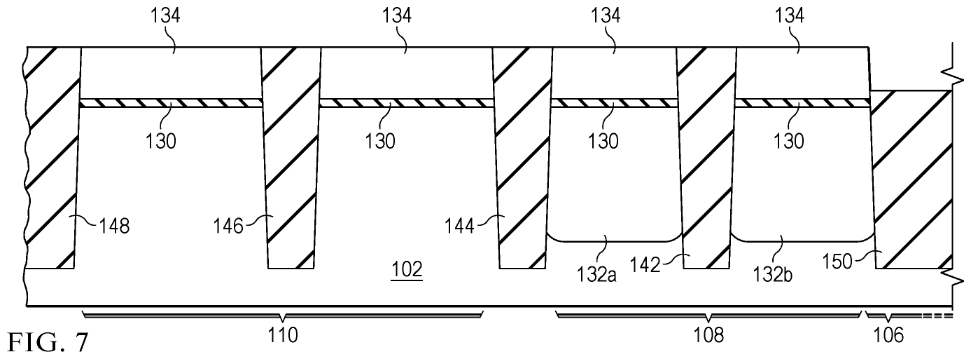

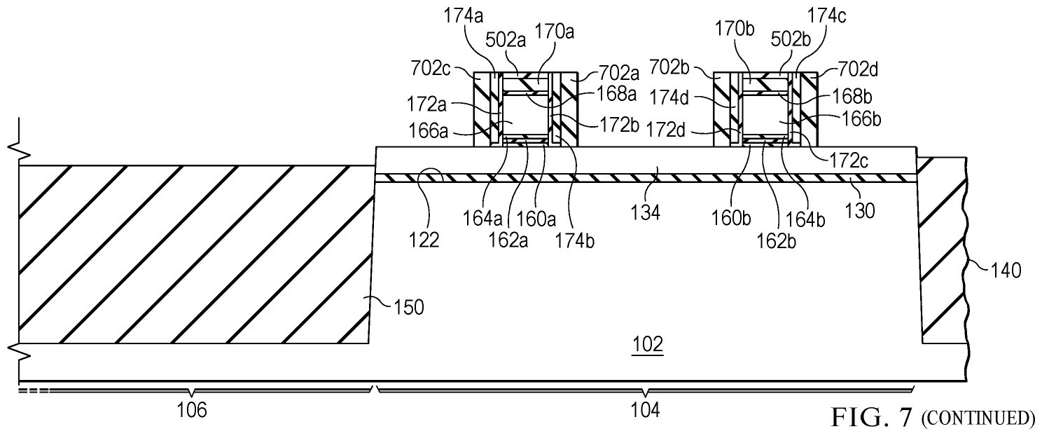

Referring to FIG. 7, the first CG dielectric spacer layer 172 and second CG dielectric spacer layer 174 are patterned into the first CG dielectric spacers 172a-172d and the second CG dielectric spacers 174a-174d, respectively. An anisotropic etch may be used to pattern the first CG dielectric spacer layer 172 and second CG dielectric spacer layer 174.

Dummy spacers 702a, 702b, 702c, 702d are formed on sidewalls of the second CG dielectric spacers 174b, 174d, 174a, 174c, respectively. The dummy spacers 702a-702d may be formed by depositing (e.g., by CVD, LPCVD, PECVD, or the like) a layer of the dummy spacers 702a-702d and patterning the layer (e.g., by an anisotropic etch) into the dummy spacers 702a-702d. The dummy spacers 702a-702d may be any material that may be selectively etched. In some examples, the dummy spacers 702a-702d are or include an oxide, such as silicon oxide.

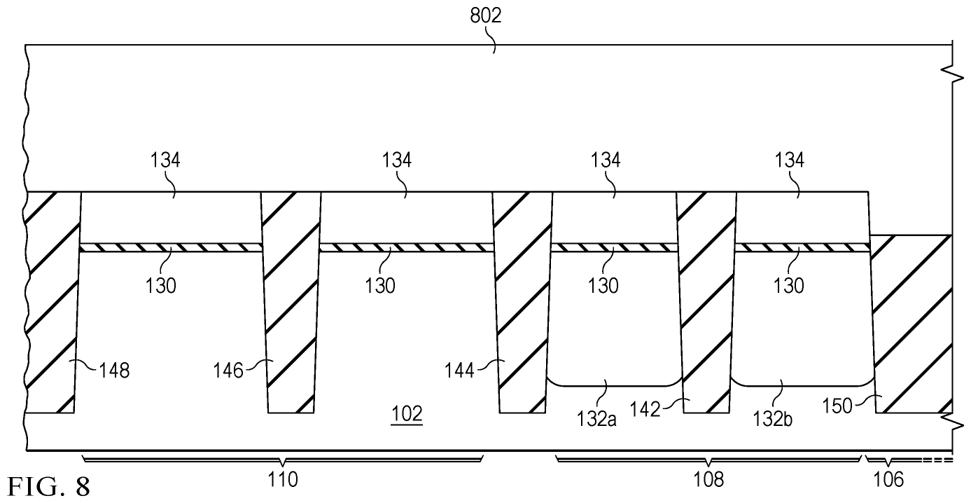

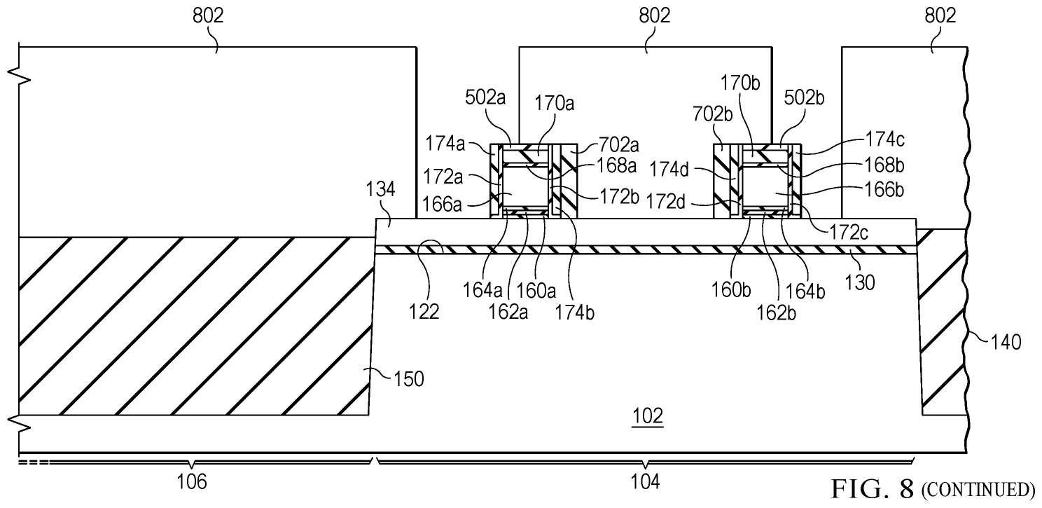

Referring to FIG. 8, the dummy spacers 702c, 702d are removed. A photoresist 802 is deposited (e.g., by spin-on) over the semiconductor substrate 102 and patterned using photolithography to have openings exposing the dummy spacers 702c, 702d. Using the photoresist 802 as a mask, an etch process is performed to selectively etch and remove the dummy spacers 702c, 702d. The etch process may include a dry etch and/or a wet etch. After the etch process, the photoresist 802 is removed, such as by ashing.

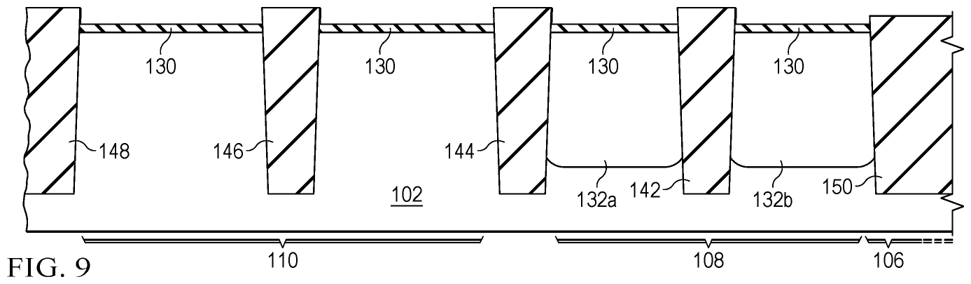

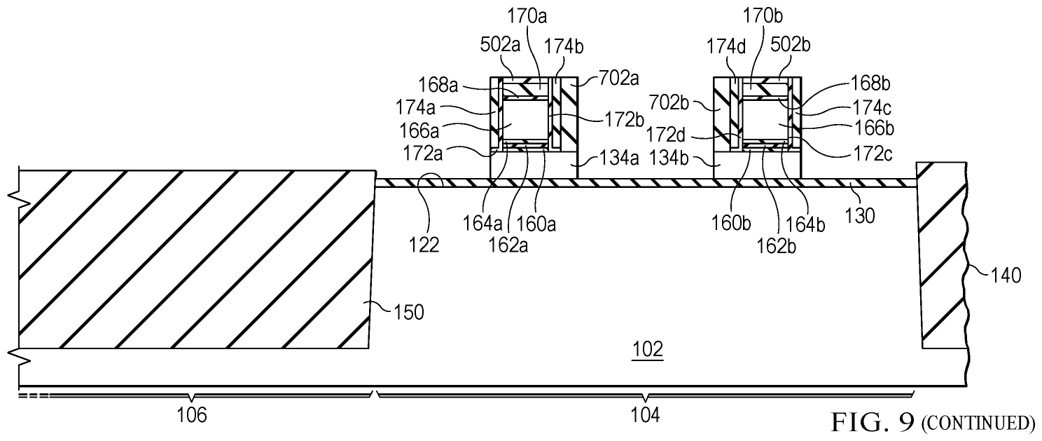

Referring to FIG. 9, the FG electrode layer 134 is patterned into FG electrodes 134a, 134b. Using, e.g., the dummy spacers 702a, 702b, dielectric cap buffer layers 502a, 502b, first CG dielectric spacers 172a-172d, and second CG dielectric spacers 174a-174d as a mask, the FG electrode layer 134 is patterned by an anisotropic etch process (e.g., an RIE). The FG electrode 134a remains underlying, among other things, the dummy spacer 702a and the CG dielectric layer (e.g., dielectric sub-layers 160a-164a), and the FG electrode 134b remains underlying, among other things, the dummy spacer 702b and the CG dielectric layer (e.g., dielectric sub-layers 160b-164b). The etch process may also etch the isolation structures 140-150, which may lower respective upper surfaces of the isolation structures 140-150.

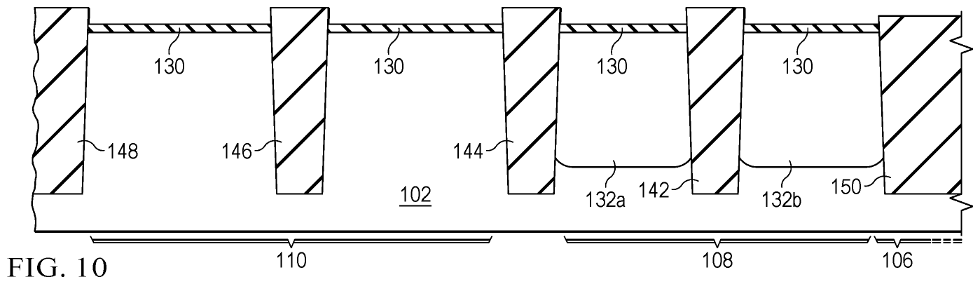

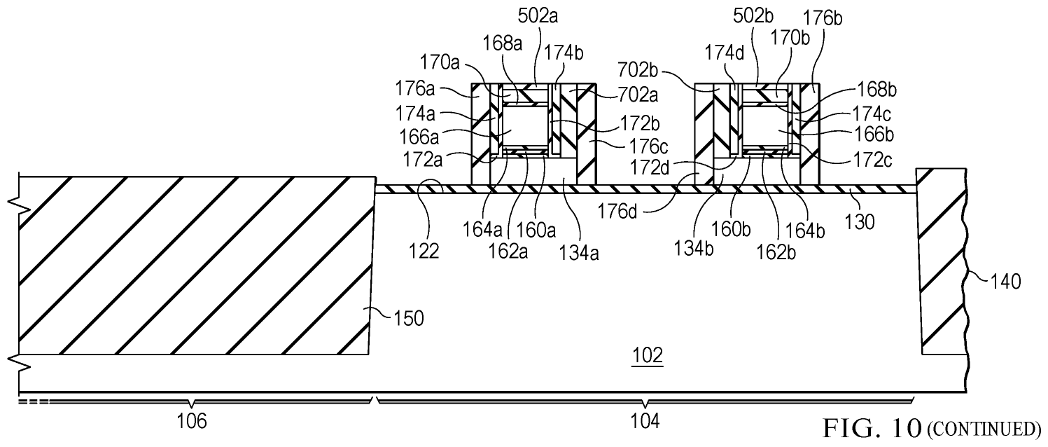

Referring to FIG. 10, first WLG dielectric spacers 176a, 176b, 176c, 176d are formed. The first WLG dielectric spacers 176a, 176b are formed on respective sidewalls of the first CG dielectric spacers 172a, 172b, second CG dielectric spacers 174a, 174b, and FG electrodes 134a, 134b. The first WLG dielectric spacer 176c is formed on respective sidewalls of the dummy spacer 702a and FG electrode 134a. The first WLG dielectric spacer 176d is formed on respective sidewalls of the dummy spacer 702b and FG electrode 134b. The first WLG dielectric spacers 176a-176d may be formed by depositing (e.g., by CVD, LPCVD, PECVD, or the like) a layer of the first WLG dielectric spacers 176a-176d and patterning the layer (e.g., by an anisotropic etch) into the first WLG dielectric spacers 176a-176d. The first WLG dielectric spacers 176a-176d may be any material described above with respect to the first WLG dielectric spacers 176a, 176b.

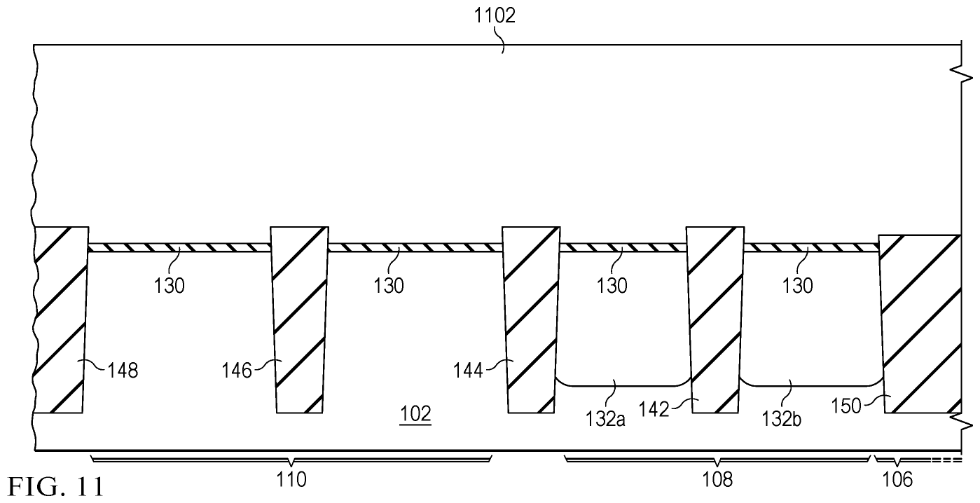

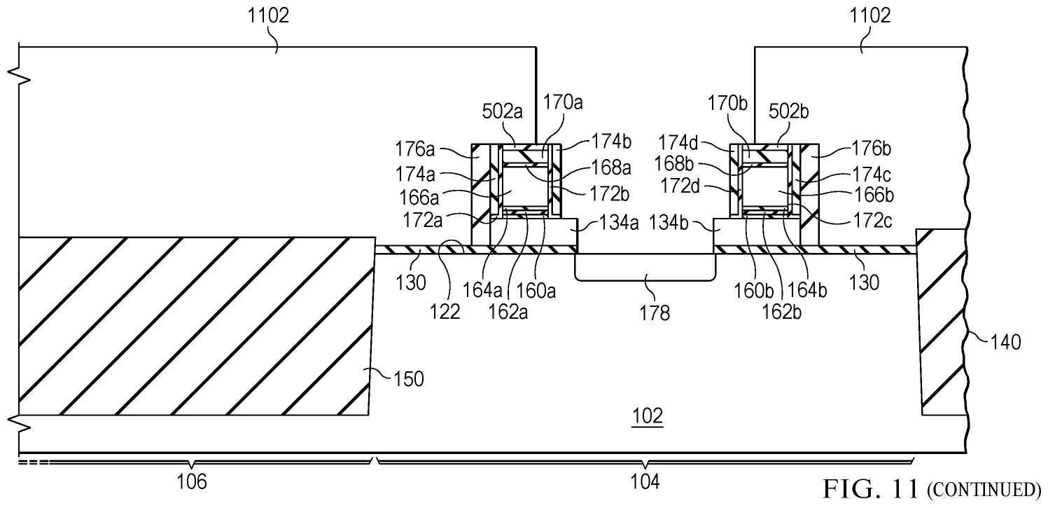

Referring to FIG. 11, shared NSD region 178 is formed. A photoresist 1102 is deposited (e.g., by spin-on) over the semiconductor substrate 102 and patterned using photolithography to have openings exposing the first WLG dielectric spacers 176c, 176d, dummy spacers 702a, 702b, and the gate dielectric layer 130 between the first WLG dielectric spacers 176c, 176d. Using the photoresist 1102 as a mask, an implantation is performed to implant dopants into the semiconductor substrate 102 to form the shared NSD region 178. A concentration of the n-type dopant of the shared NSD region 178 may be as described above.

Then, the first WLG dielectric spacers 176c, 176d, dummy spacers 702a, 702b, and gate dielectric layer 130 laterally between the FG electrodes 134a, 134b are removed. Using the photoresist 1102 as a mask, an etch process is performed to selectively etch and remove the first WLG dielectric spacers 176c, 176d, dummy spacers 702a, 702b, and exposed gate dielectric layer 130. The etch process may include a dry etch and/or a wet etch. The upper surface 122 of the semiconductor substrate 102 is exposed after the exposed gate dielectric layer 130 is removed. After the etch process, the photoresist 1102 is removed, such as by ashing.

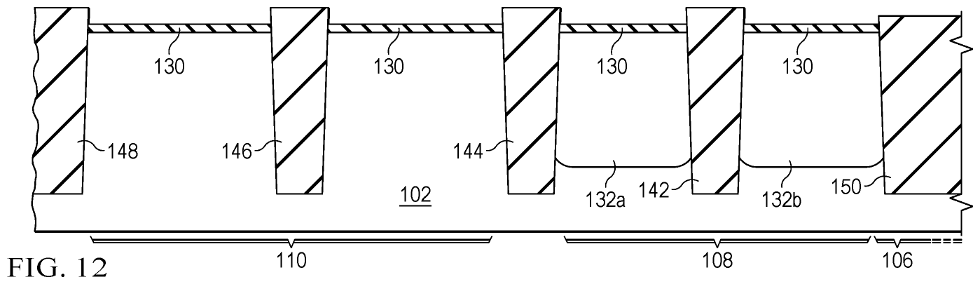

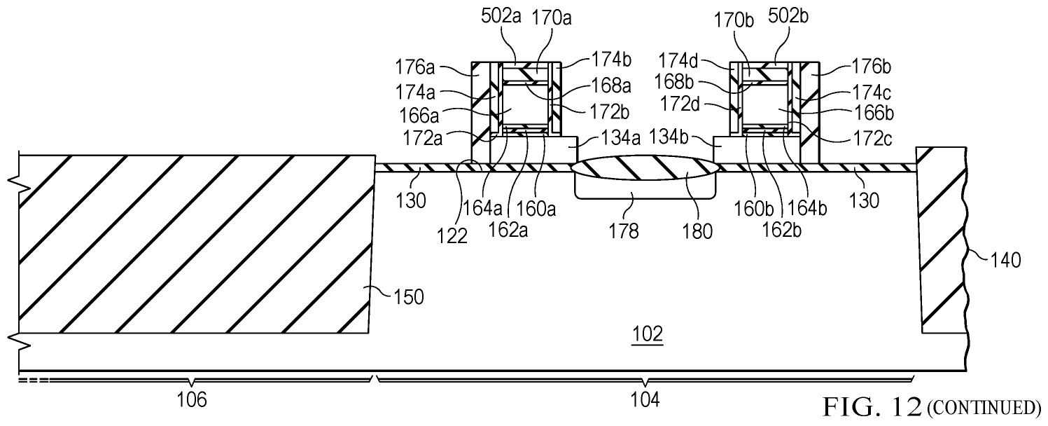

Referring to FIG. 12, an isolation structure 180 is formed at the upper surface 122 laterally between the FG electrodes 134a, 134b. The upper surface 122 of the semiconductor substrate 102 laterally between the FG electrodes 134a, 134b is oxidized to form the isolation structure 180. For example, the oxidation may be a thermal oxidation. The oxidation may be dependent upon the implantation to form the shared NSD region 178. For example, the implantation may amorphize the semiconductor substrate 102 where the implantation is performed. The extend of the amorphization may determine the rate at which the semiconductor substrate 102 is oxidized.

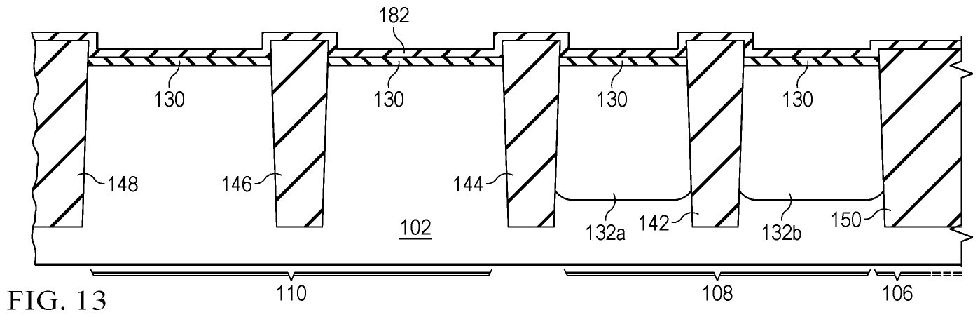

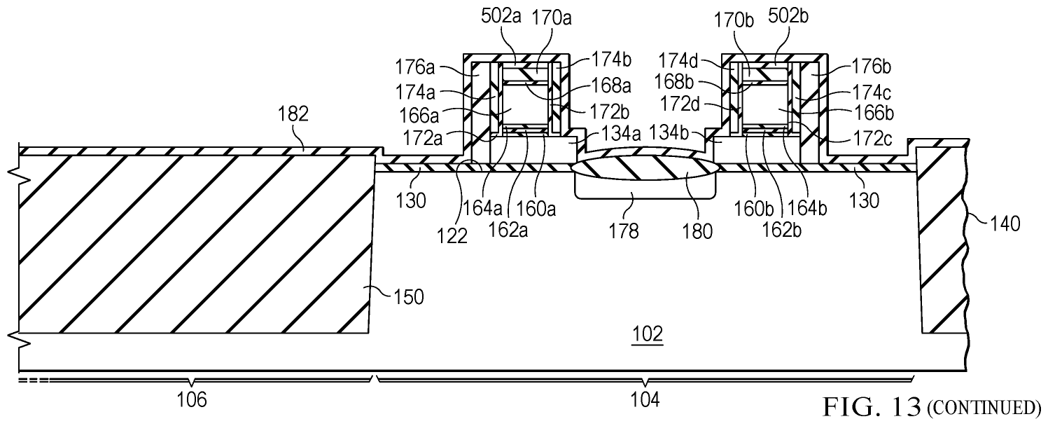

Referring to FIG. 13, a spacer/tunnel dielectric layer 182 is formed over the semiconductor substrate 102. The spacer/tunnel dielectric layer 182 is formed conformally over the dielectric cap buffer layers 502a, 502b, first CG dielectric spacers 172a-172d, second CG dielectric spacers 174a-174d, first WLG dielectric spacers 176a, 176b, FG electrodes 134a, 134b, and isolation structure 180. The spacer/tunnel dielectric layer 182 may be any material described above with respect to the second WLG dielectric spacers 182a, 182b and tunnel dielectric layer 182c. The spacer/tunnel dielectric layer 182 may be formed using any appropriate deposition process, such as CVD, LPCVD, PECVD, or the like. In some examples, such as when the spacer/tunnel dielectric layer 182 is an oxide (e.g., silicon oxide), no nitridation of the spacer/tunnel dielectric layer 182 is performed to form the spacer/tunnel dielectric layer 182.

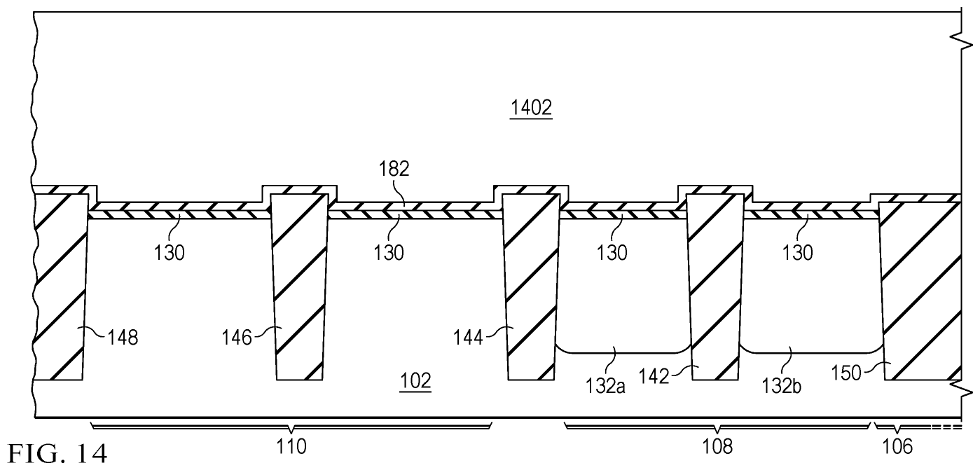

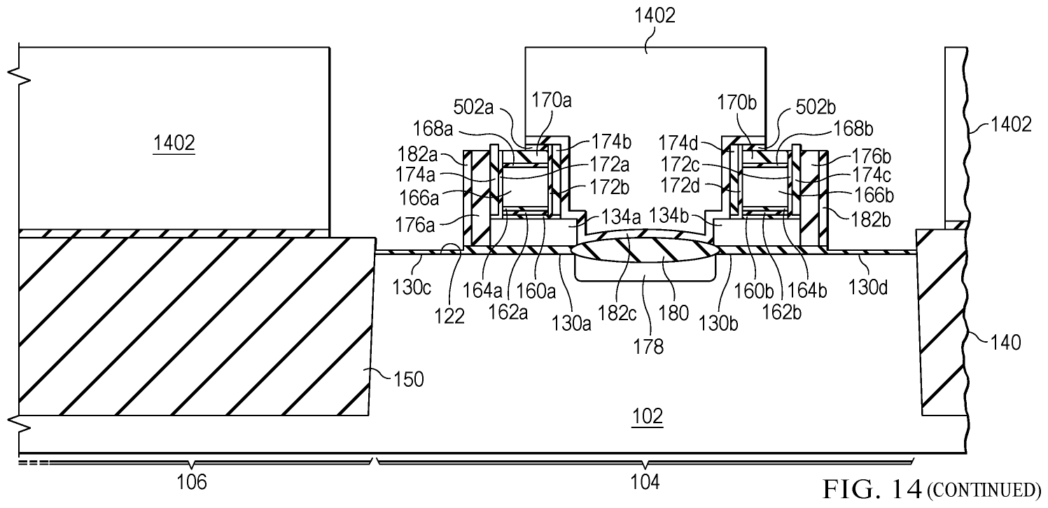

Referring to FIG. 14, the spacer/tunnel dielectric layer 182 is patterned into the second WLG dielectric spacers 182a, 182b. The spacer/tunnel dielectric layer 182 over the gate dielectric layer 130 extending laterally from the respective first WLG dielectric spacer 176a, 176b is removed. A photoresist 1402 is deposited (e.g., by spin-on) over the semiconductor substrate 102 and patterned using photolithography to have openings exposing the spacer/tunnel dielectric layer 182. Using the photoresist 1402 as a mask, an anisotropic etch process (e.g., an RIE) is performed to pattern the second WLG dielectric spacers 182a, 182b and remove lateral portions of the spacer/tunnel dielectric layer 182. Patterning the spacer/tunnel dielectric layer 182 further causes the tunnel dielectric layer 182c to generally be patterned from the spacer/tunnel dielectric layer 182.

The etch process may further etch the gate dielectric layer 130 that is exposed by removing the exposed lateral portions of the spacer/tunnel dielectric layer 182. Further etching the gate dielectric layer 130 results in WLG dielectric layers 130c, 130d, which may be thinner than the FG dielectric layers 130a, 130b. In some examples, the etch process may completely etch the gate dielectric layer 130 that is exposed by removing the exposed lateral portions of the spacer/tunnel dielectric layer 182. Subsequently, WLG dielectric layers 130c, 130d may form (e.g., grow) on the exposed upper surface 122 of the substrate 102. In such implementations, the WLG dielectric layers 130c, 130d may be independently thinned or formed such that thicknesses of the WLG dielectric layers 130c, 130d may be optimized generally without constraints of, e.g., gate dielectric layers 202-208 of the pFETs 114, 116 and nFETs 118, 120. The etch process may also etch other components of a same material, such as, as illustrated, the first WLG dielectric spacers 176a, 176b, first CG dielectric spacers 172a, 172b, and dielectric cap buffer layers 502a, 502b. After the etch process, the photoresist 1402 is removed, such as by ashing.

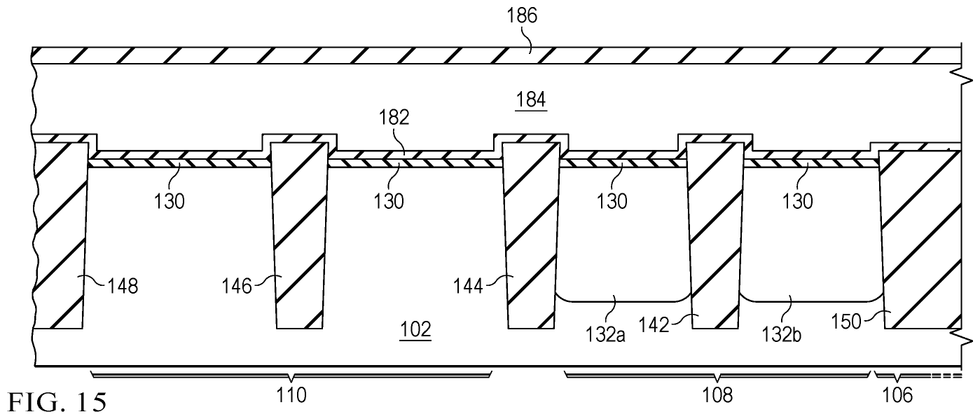

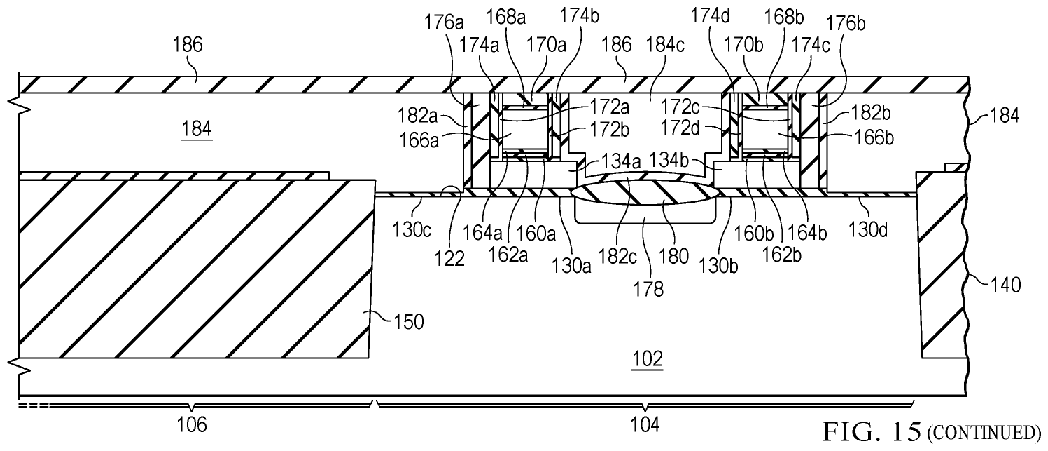

Referring to FIG. 15, a conductive layer 184 is formed over the semiconductor substrate 102. The conductive layer 184 is formed over the spacer/tunnel dielectric layer 182, second WLG dielectric spacers 182a, 182b, tunnel dielectric layer 182c, WLG dielectric layers 130c, 130d, and dielectric cap buffer layers 502a, 502b, among others. The conductive layer 184 may be any material described above with respect to the WLG electrodes 184a, 184b and shared EG electrode 184c. The conductive layer 184 may be formed using any appropriate deposition process, such as CVD, PECVD, physical vapor deposition (PVD), or the like. The conductive layer 184 may be doped (e.g., by in situ doping during deposition and/or implantation subsequent to deposition) to a concentration described above with respect to the WLG electrodes 184a, 184b and shared EG electrode 184c.

The conductive layer 184 is planarized to have a top surface co-planar with respective top surfaces of the second dielectric cap layers 170a, 170b. Planarizing the conductive layer 184 in this manner patterns a portion of the conductive layer 184 into the shared EG electrode 184c laterally between the CG electrodes 166a, 166b and laterally between the FG electrodes 134a, 134b over the isolation structure 180. The planarization may be by a CMP. The planarization may also remove the dielectric cap buffer layers 502a, 502b and portions of the tunnel dielectric layer 182c, first CG dielectric spacers 172a-172d, and second CG dielectric spacers 174a-174d at levels above the top surfaces of the second dielectric cap layers 170a, 170b. Although not illustrated, dishing may occur in the conductive layer 184, such as in the pFET region 108 and nFET region 110.

A protective dielectric layer 186 is formed over the conductive layer 184, shared EG electrode 184c, and dielectric cap buffer layers 502a, 502b, among others. The protective dielectric layer 186 may be any material described above with respect to the protective dielectric layer 186. The protective dielectric layer 186 may be formed using any appropriate deposition process, such as CVD, PECVD, PVD, or the like.

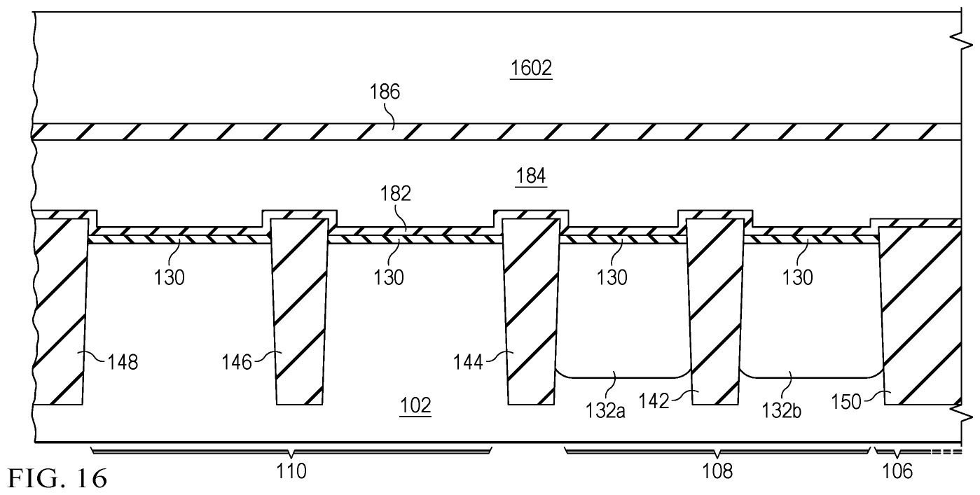

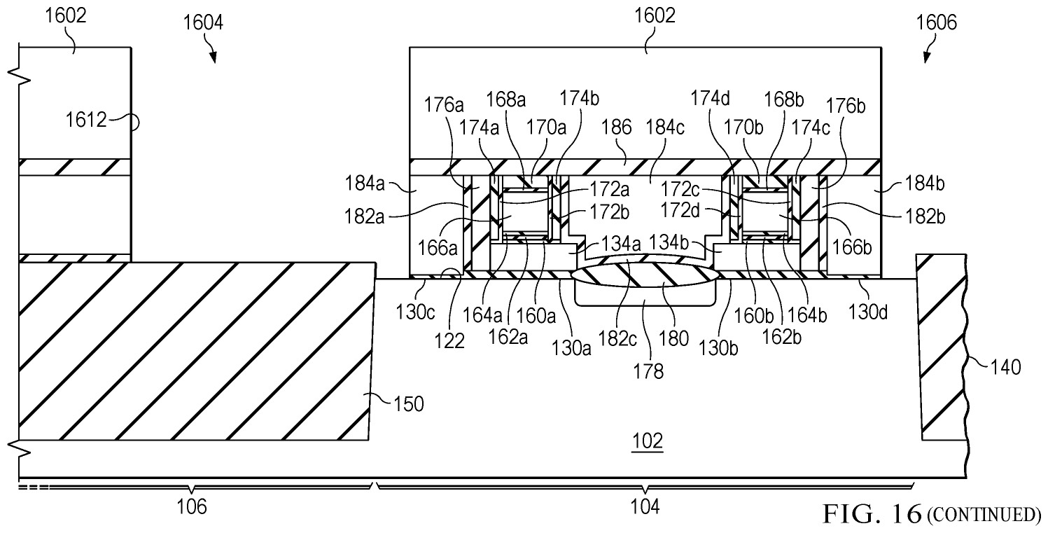

Referring to FIG. 16, the conductive layer 184 is further patterned into WLG electrodes 184a, 184b over the respective WLG dielectric layers 130c, 130d. A photoresist 1602 is deposited (e.g., by spin-on) over the semiconductor substrate 102 and patterned using photolithography to have openings 1604, 1606 exposing the protective dielectric layer 186. The opening 1604 through the photoresist 1602 has a sidewall that is in the flash memory region 104 and a sidewall 1612 that is in the transition region 106, and hence, the opening 1604 extends from the flash memory region 104 into the transition region 106. The opening 1606 through the photoresist 1602 has a sidewall that is in the flash memory region 104 and a sidewall that is in another region (e.g., another transition region), and hence, the opening 1606 extends from the flash memory region 104 into the other region. Using the photoresist 1602 as a mask, an anisotropic etch process (e.g., an RIE) is performed to pattern the protective dielectric layer 186 and conductive layer 184. The etch process may further remove the spacer/tunnel dielectric layer 182 and WLG dielectric layers 130c, 130d laterally within the openings 1604, 1606 and expose respective portions of the upper surface 122 of the semiconductor substrate 102, as illustrated. After the etch process, the photoresist 1602 is removed, such as by ashing.

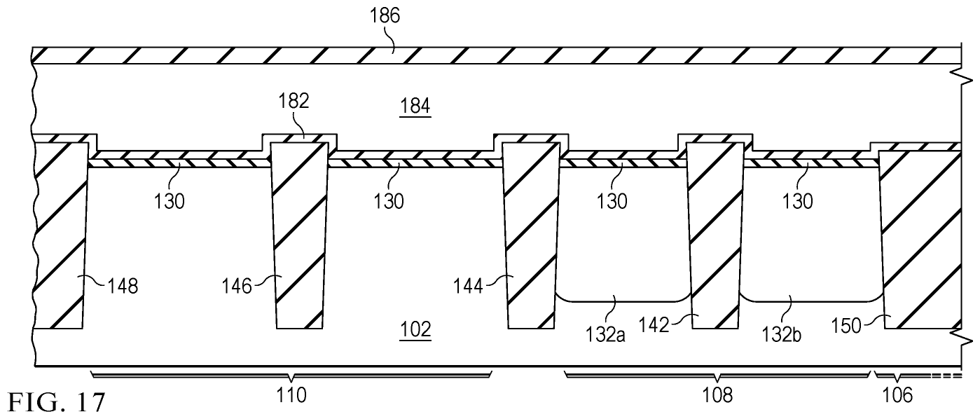

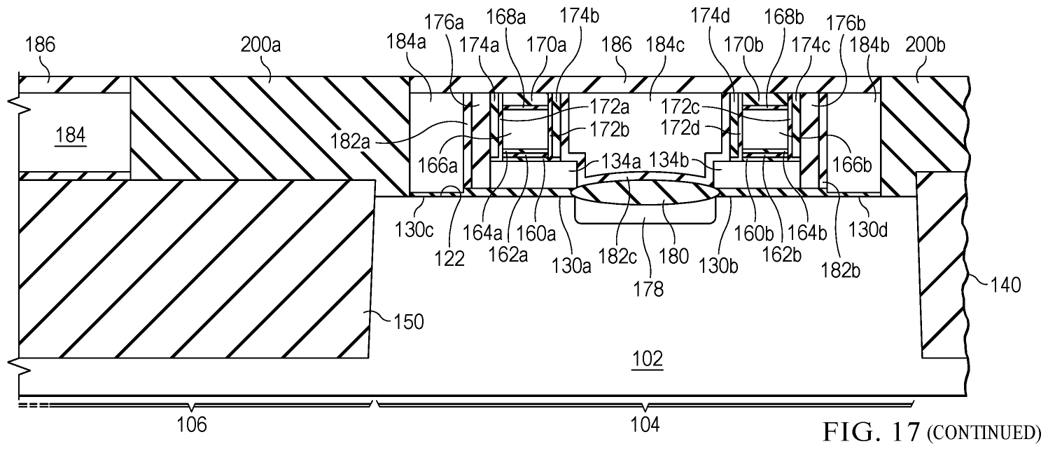

Referring to FIG. 17, protective dielectrics 200a, 200b are formed where the conductive layer 184 was removed in FIG. 16. The protective dielectric 200a is formed on and along sidewalls of the WLG electrode 184a, protective dielectric layer 186, and WLG dielectric layer 130c and over the portion of the upper surface 122 of the semiconductor substrate 102 laterally between the WLG dielectric layer 130c and the isolation structure 150. The protective dielectric 200a is further formed over the isolation structure 150 and on and along sidewalls of the protective dielectric layer 186, conductive layer 184, and spacer/tunnel dielectric layer 182 in the transition region 106. The protective dielectric 200b is formed on and along sidewalls of the WLG electrode 184b, protective dielectric layer 186, and WLG dielectric layer 130d and over the portion of the upper surface 122 of the semiconductor substrate 102 laterally between the WLG dielectric layer 130d and the isolation structure 140. The protective dielectrics 200a, 200b may be any material described above with respect to the protective dielectric 200a. The protective dielectrics 200a, 200b may be formed using any appropriate deposition process, such as CVD, PECVD, PVD, or the like and using a planarization technique, such as a CMP, to remove excess protective dielectric material from over the protective dielectric layer 186.

Following the processing for FIG. 17, the various layers, electrodes, and spacers that form the flash memory mirrored bit pair cell 112 have been formed. As illustrated subsequently, some implantations to form LDDs and NSDs may be formed subsequently. Further, as detailed subsequently, no layer, electrode, or spacer of any FET has been formed. The processing illustrated permits generally independent processing to form the flash memory mirrored bit pair cell 112 from the processing to form the FETs 114-120. This permits the processing to be more modular, which may permit inserting or removing flash memory processing into or from, e.g., CMOS processing more easily.

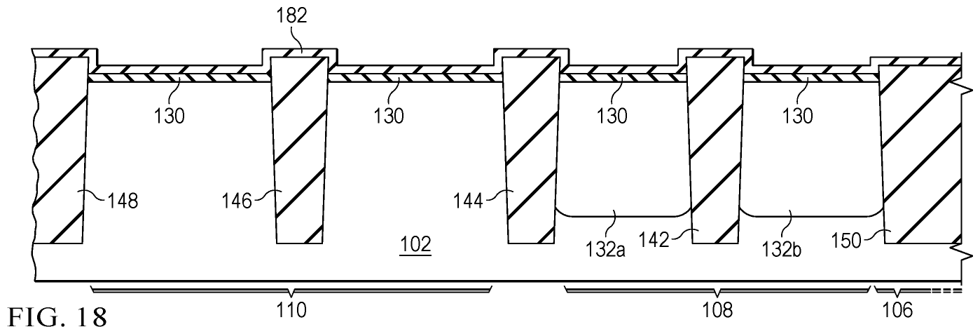

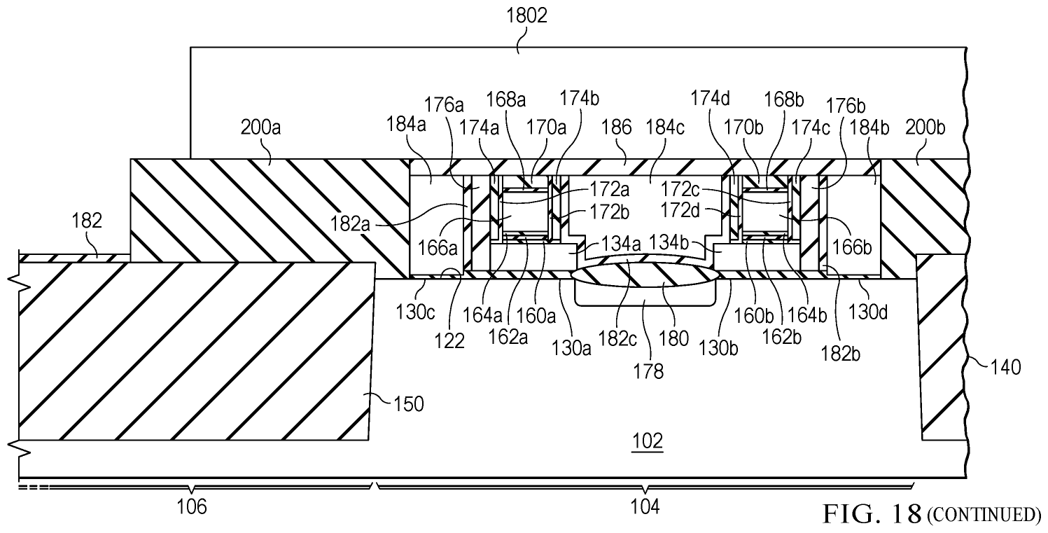

Referring to FIG. 18, the protective dielectric layer 186 and conductive layer 184 in the transition region 106, pFET region 108, and nFET region 110 are removed. A photoresist 1802 is deposited (e.g., by spin-on) over the semiconductor substrate 102 and patterned using photolithography to expose the protective dielectric layer 186 in the transition region 106, pFET region 108, and nFET region 110. The protective dielectrics 200a, 200b permit tolerance for misalignment of the patterning of the photoresist 1802. Using the photoresist 1802 as a mask, an etch process is performed to selectively remove the protective dielectric layer 186 and conductive layer 184 in the transition region 106, pFET region 108, and nFET region 110. The etch process may include a dry etch and/or a wet etch. After the etch process, the photoresist 1802 is removed, such as by ashing.

Gate dielectric layers 202, 204, 206, 208 are formed. Generally, in some examples, the spacer/tunnel dielectric layer 182 and gate dielectric layer 130 on an active area where a FET with a highest operating voltage rating is to be formed are removed with an oxidation following the removal. The spacer/tunnel dielectric layer 182 and gate dielectric layer 130 on active areas on which FETs with next highest operating voltage rating are removed with subsequent oxidations following the respective removal. The active area where the spacer/tunnel dielectric layer 182 and gate dielectric layer 130 were first removed is oxidized the most, and hence, the gate dielectric layer formed on that active area is thickest. The active area where the spacer/tunnel dielectric layer 182 and gate dielectric layer 130 were last removed is oxidized the least, and hence, the gate dielectric layer formed on that active area is thinnest. In such examples, the gate dielectric layers 202, 204, 206, 208 are or include an oxide, such as silicon oxide.

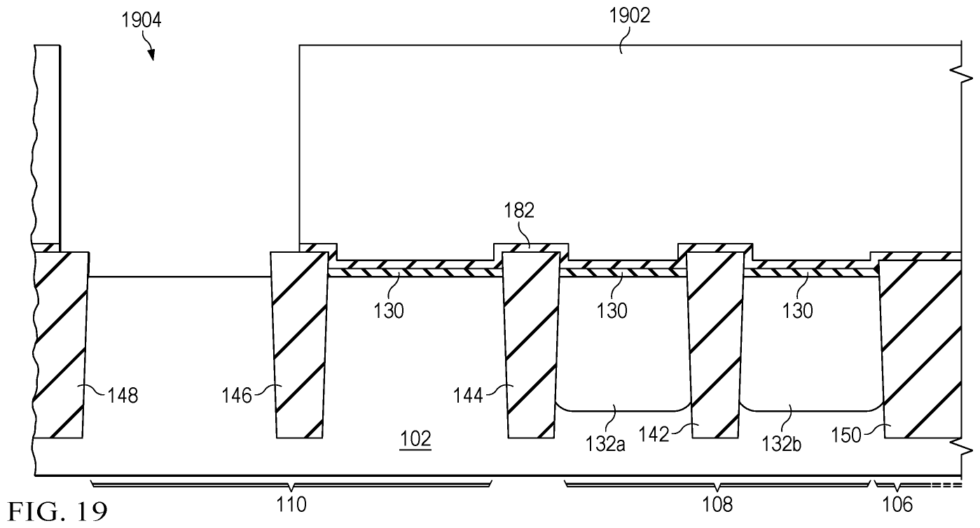

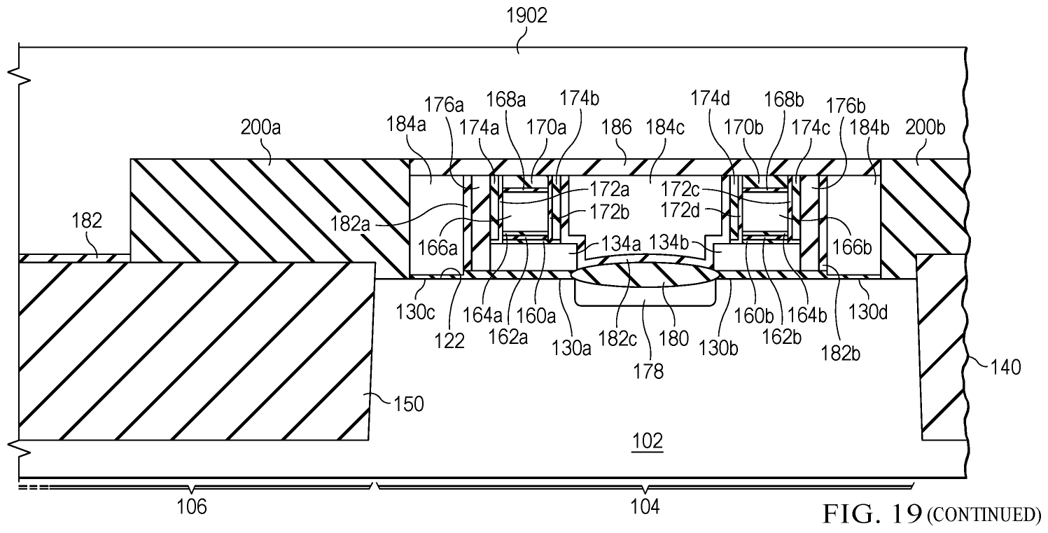

As an illustration, referring to FIG. 19, a photoresist 1902 is deposited (e.g., by spin-on) over the semiconductor substrate 102 and patterned using photolithography to form an opening 1904 exposing the spacer/tunnel dielectric layer 182 where the second nFET 120 is to be formed. Using the photoresist 1902 as a mask, an etch process is performed to selectively remove the spacer/tunnel dielectric layer 182 and gate dielectric layer 130 from the active area in which the second nFET 120 is to be formed. The etch process may include a dry etch and/or a wet etch. After the etch process, the photoresist 1902 is removed, such as by ashing.

Next, although not illustrated, an oxidation process, such as ISSG oxidation, is performed to oxidize the upper surface 122 of the semiconductor substrate 102. Then, the spacer/tunnel dielectric layer 182 and gate dielectric layer 130 are removed from the active area in which the first nFET 118 is to be formed, similar to how the spacer/tunnel dielectric layer 182 and gate dielectric layer 130 are removed previously. Then, another oxidation process is performed to oxidize the upper surface 122 of the semiconductor substrate 102. Then, the spacer/tunnel dielectric layer 182 and gate dielectric layer 130 are removed from the active area in which the second pFET 116 is to be formed. Then, another oxidation process is performed to oxidize the upper surface 122 of the semiconductor substrate 102. Then, the spacer/tunnel dielectric layer 182 and gate dielectric layer 130 are removed from the active area in which the first pFET 114 is to be formed. Then, another oxidation process is performed to oxidize the upper surface 122 of the semiconductor substrate 102.

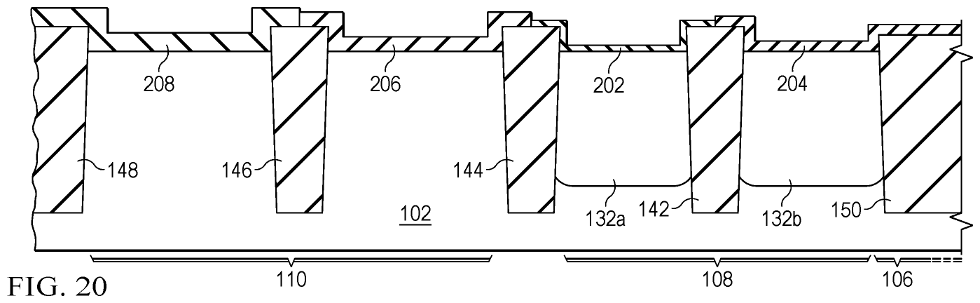

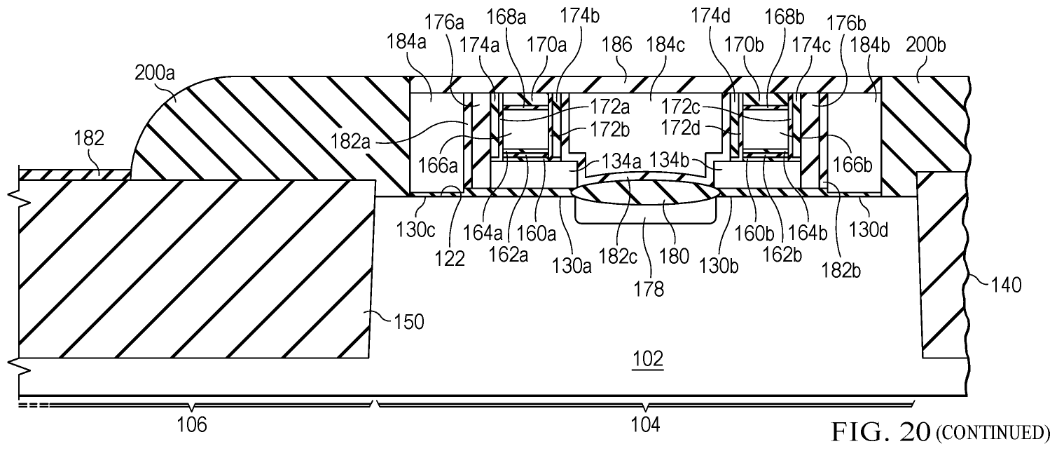

As shown in FIG. 20, as a result of the oxidation processes and following the oxidation process following the removal of the spacer/tunnel dielectric layer 182 and gate dielectric layer 130 from the active area in which the first pFET 114 is to be formed, the gate dielectric layers 202, 204, 206, 208 are formed. In the illustrated example, the gate dielectric layer 208 is the result of four oxidation processes; the gate dielectric layer 206 is the result of three oxidation processes; the gate dielectric layer 204 is the result of two oxidation processes; and the gate dielectric layer 202 is the result of one oxidation process. Hence, the gate dielectric layer 208 is thicker than the gate dielectric layer 206; the gate dielectric layer 206 is thicker than the gate dielectric layer 204; and the gate dielectric layer 204 is thicker than the gate dielectric layer 202.

Following the oxidation processes, a nitridation process is performed on the gate dielectric layers 202, 204, 206, 208. The nitridation process may include a decoupled plasma nitridation (DPN) followed by a post nitridation anneal (PNA). The nitridation process drives nitrogen-containing species into the gate dielectric layers 202, 204, 206, 208 (e.g., in contrast to residual nitrogen-containing species remaining on an exposed surface of the gate dielectric layers 202, 204, 206, 208, which may occur in an anneal in a nitrogen-containing ambient). Hence, in such examples, the gate dielectric layers 202, 204, 206, 208 may be or include nitrided silicon oxide.

During the nitridation process, the WLG dielectric layers 130c, 130d, tunnel dielectric layer 182c, and second WLG dielectric spacers 182a, 182b, among other dielectric layers in the flash memory region 104, are protected and/or masked from the nitridation process. By being protected and/or masked, nitriding is blocked from reaching the WLG dielectric layers 130c, 130d, tunnel dielectric layer 182c, and second WLG dielectric spacers 182a, 182b, among other dielectric layers in the flash memory region 104. Hence, following the nitridation process, the WLG dielectric layers 130c, 130d, tunnel dielectric layer 182c, and second WLG dielectric spacers 182a, 182b are free from nitridation. Among other things, the protective dielectrics 200a, 200b, protective dielectric layer 186, and WLG electrodes 184a, 184b may prevent a nitrogen-containing species from reaching the WLG dielectric layers 130c, 130d and second WLG dielectric spacers 182a, 182b during the nitridation process. Among other things, the protective dielectric layer 186 and shared EG electrode 184c may prevent a nitrogen-containing species from reaching the tunnel dielectric layer 182c during the nitridation process. This processing permits the WLG dielectric layers 130c, 130d, tunnel dielectric layer 182c, and second WLG dielectric spacers 182a, 182b to have characteristics separate from any constraints of the gate electrodes 210a-210d, which may permit the WLG dielectric layers 130c, 130d, tunnel dielectric layer 182c, and second WLG dielectric spacers 182a, 182b to be more optimized for the flash memory mirrored bit pair cell 112.

As also shown in FIG. 20, the protective dielectric 200a (and protective dielectric 200b, although not illustrated) may develop a rounded corner in the transition region 106 during semiconductor processing to form the gate dielectric layers 202-208. After removal of the conductive layer 184 from the transition region 106 as described with respect to FIG. 17, the sidewall of the protective dielectric 200a that was previously adjoining a sidewall of the conductive layer 184 may be exposed to, e.g., etch processes, cleaning process, and/or ashing processes during the formation of the gate dielectric layers 202-208. Such processes may round the corner that was formed by that sidewall of the protective dielectric 200a and the top surface of the protective dielectric 200a.

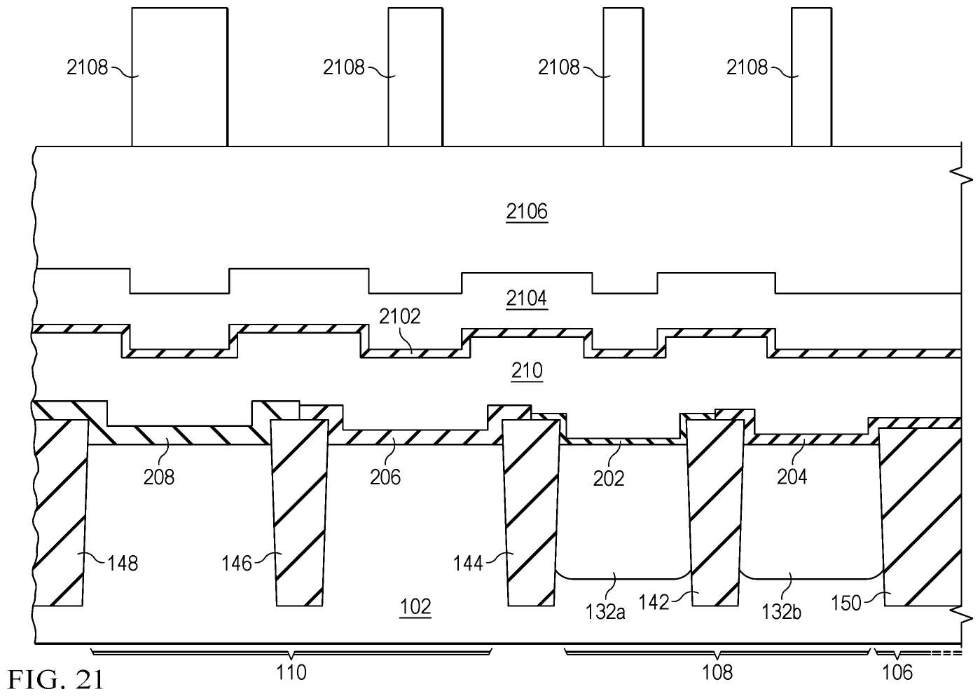

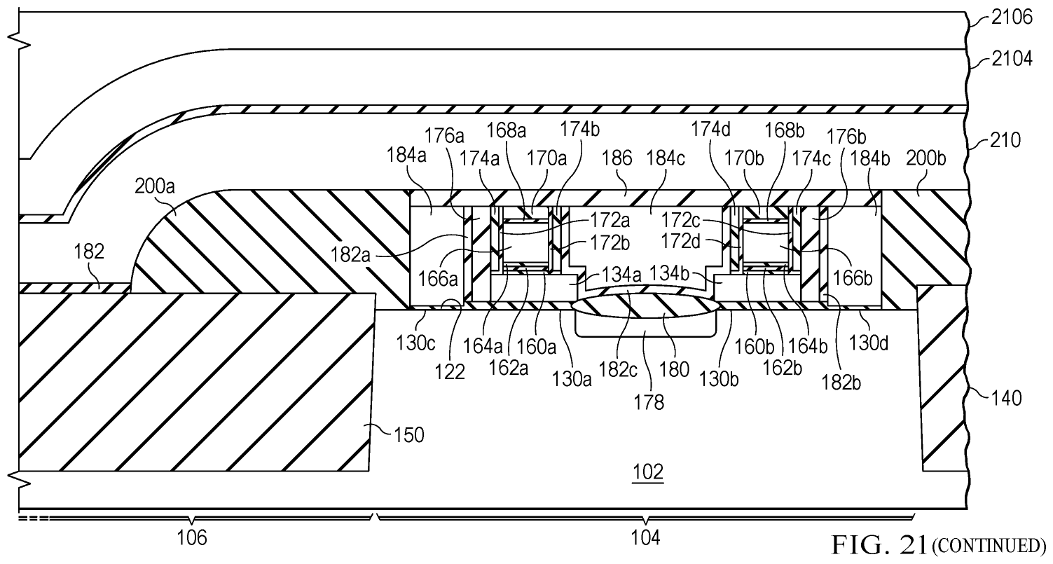

Referring to FIG. 21, a gate electrode layer 210 is formed over the semiconductor substrate 102 (e.g., over the gate dielectric layers 202-208, protective dielectrics 200a, 200b, and protective dielectric layer 186). The gate electrode layer 210 may be any material described above with respect to the gate electrodes 210a-210d. The gate electrode layer 210 may be formed using any appropriate deposition process, such as CVD, PECVD, PVD, or the like. In some examples, the gate electrode layer 210 is or includes a semiconductor material, such as polycrystalline silicon (polysilicon). In some examples, the semiconductor material may be doped in situ during deposition and/or may be implanted by a dopant after deposition. In some examples, the gate electrode layer 210 in the pFET region 108 is polysilicon doped with a p-type dopant with a concentration in a range from 1×10¹⁹ cm⁻³ to 1×10²¹ cm⁻³ after deposition and/or implantation, and the gate electrode layer 210 in the nFET region 110 is polysilicon doped with an n-type dopant with a concentration in a range from 5×10¹⁹ cm⁻³ to 5×10²¹ cm⁻³ after implantation. The flash memory region 104 may be masked (e.g., by a photoresist) during any implantation of the gate electrode layer 210. Other materials (e.g., conductive material) may be implemented as the gate electrode layer 210, which may be formed by any deposition process.

A protective dielectric layer 2102 is formed over the gate electrode layer 210. In some examples, the protective dielectric layer 2102 is silicon oxide deposited by CVD, although other dielectric materials and/or other deposition processes may be used in other examples.

A hardmask layer 2104 is formed conformally over the protective dielectric layer 2102. In some examples, the hardmask layer 2104 is or includes silicon nitride deposited by CVD, although other hardmask (e.g., dielectric) materials and/or other deposition processes may be used in other examples.

An underlayer 2106 is formed over the hardmask layer 2104. The underlayer 2106 may include one or more sub-layers, such as a fill layer (e.g., to provide a planarized surface over which a photoresist is to be formed) and an anti-reflection coating (ARC) layer. The underlayer 2106 may be or include organic and/or inorganic materials (such as in a tri-layer patterning scheme) or the like. The underlayer 2106 may be formed by using spin-on coating or the like.

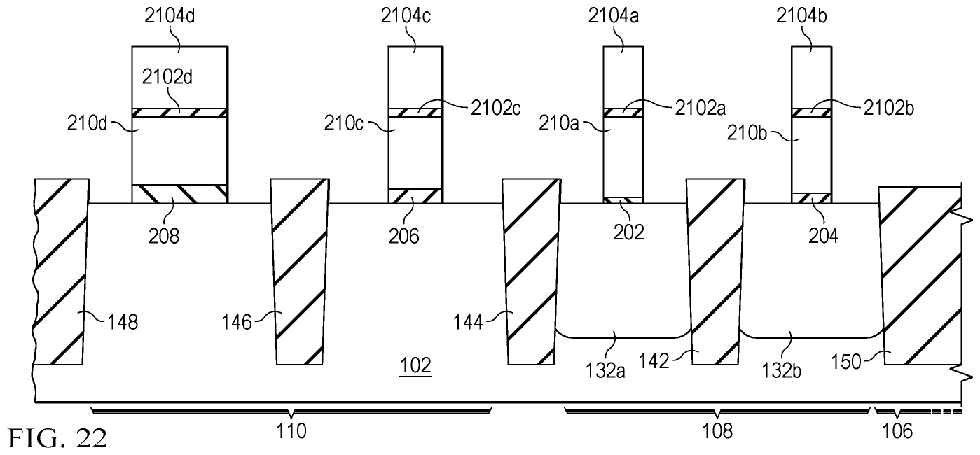

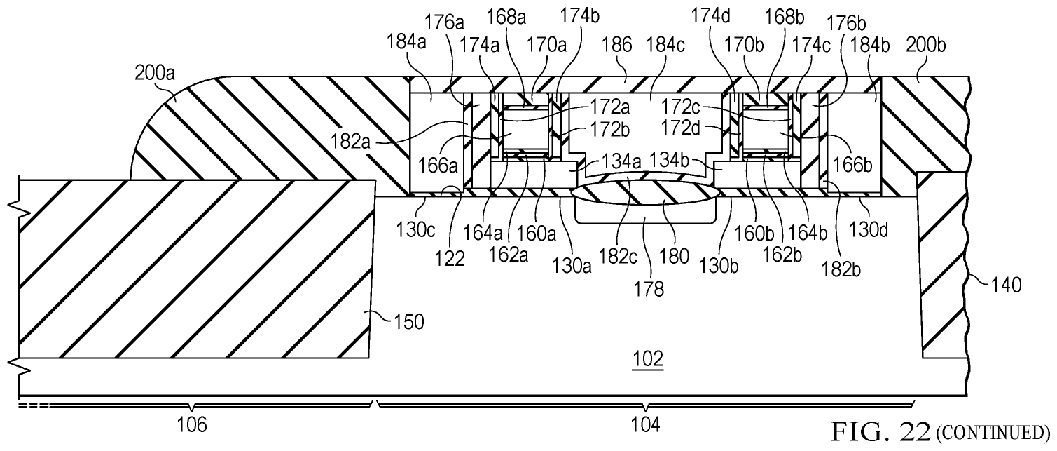

A photoresist 2108 is deposited (e.g., by spin-on) on or over the underlayer 2106 and patterned using photolithography. The photoresist 2108 is patterned to remain where gate electrodes 210a-210d are to be formed. Using the patterned photoresist 2108 as a mask, an etch process (e.g., an RIE) is performed to pattern the hardmask layer 2104, protective dielectric layer 2102, and the gate electrode layer 210, as shown in FIG. 22. The gate electrode layer 210 is patterned into gate electrodes 210a-210d. The protective dielectric layer 2102 is patterned into protective dielectric layers 2102a, 2102b, 2102c, 2102d. The hardmask layer 2104 is patterned into hardmask layers 2104a, 2104b, 2104c, 2104d. The protective dielectric layer 2102a is over the gate electrode 210a, and the hardmask layer 2104a is over the protective dielectric layer 2102a. The protective dielectric layer 2102b is over the gate electrode 210b, and the hardmask layer 2104b is over the protective dielectric layer 2102b. The protective dielectric layer 2102c is over the gate electrode 210c, and the hardmask layer 2104c is over the protective dielectric layer 2102c. The protective dielectric layer 2102d is over the gate electrode 210d, and the hardmask layer 2104d is over the protective dielectric layer 2102d. After the etch process, the photoresist 2108 and underlayer 2106 are removed, such as by ashing and/or etching processes (e.g., wet etches) selective to materials of those layers.

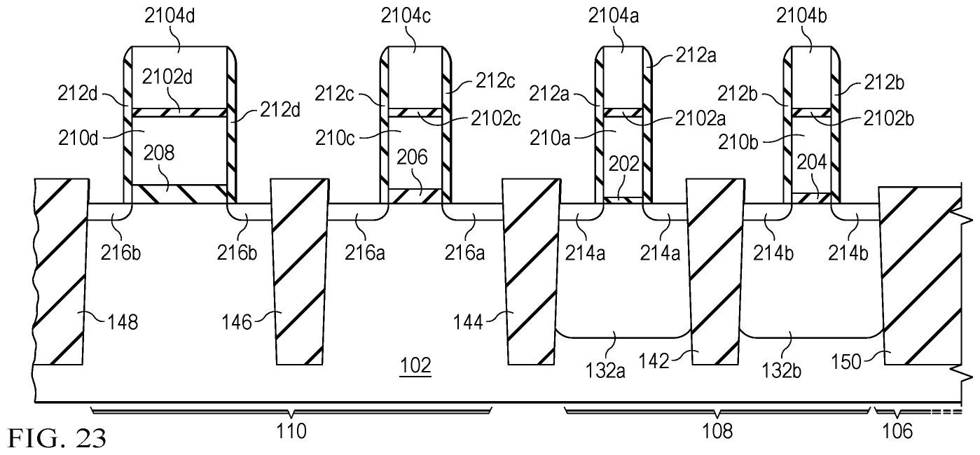

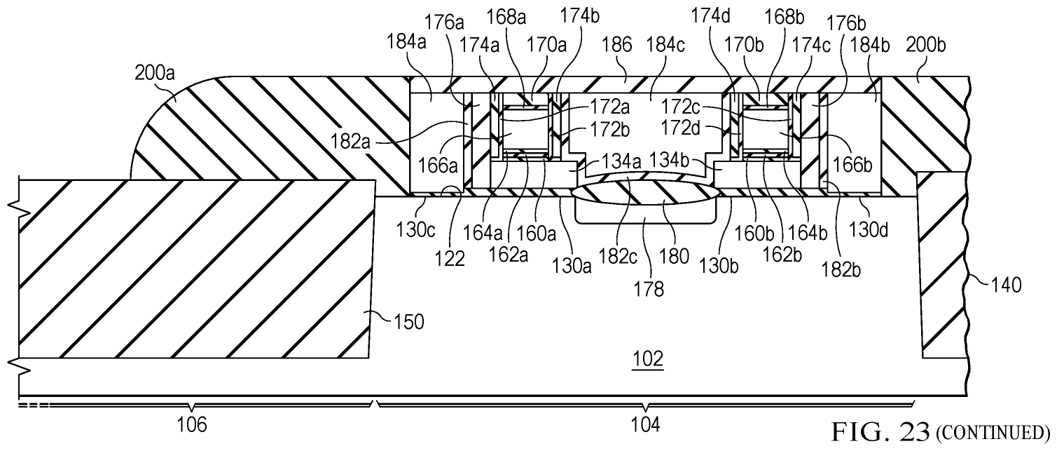

Referring to FIG. 23, first gate dielectric spacers 212a, 212b, 212c, 212d are formed along sidewalls of the gate electrodes 210a, 210b, 210c, 210d. The first gate dielectric spacers 212a, 212b, 212c, 212d may be formed by depositing a layer of the material of the first gate dielectric spacers 212a, 212b, 212c, 212d conformally over the semiconductor substrate 102 and anisotropically etching the layer such that the first gate dielectric spacers 212a, 212b, 212c, 212d remain. The first gate dielectric spacers 212a, 212b, 212c, 212d may be any material described above with respect to those components. The layer may be deposited by CVD, PECVD, ALD, or the like.

P-type LDDs 214a, 214b and n-type LDDs 216a, 216b are formed in the semiconductor substrate 102 in the pFET region 108 and the nFET region 110, respectively. The p-type LDDs 214a are in the semiconductor substrate 102 on laterally opposing sides of the gate electrode 210a, and the p-type LDDs 214b are in the semiconductor substrate 102 on laterally opposing sides of the gate electrode 210b. The n-type LDDs 216a are in the semiconductor substrate 102 on laterally opposing sides of the gate electrode 210c, and the n-type LDDs 216b are in the semiconductor substrate 102 on laterally opposing sides of the gate electrode 210d. The p-type LDDs 214a, 214b may be formed by masking (e.g., by a photoresist using photolithography) the flash memory region 104, transition region 106, and nFET region 110 and implanting a p-type dopant into the semiconductor substrate 102 in the pFET region 108. The n-type LDDs 216a, 216b may be formed by masking (e.g., by a photoresist using photolithography) the flash memory region 104, transition region 106, and pFET region 108 and implanting an n-type dopant into the semiconductor substrate 102 in the nFET region 110. Concentrations of the dopants may be as described previously.

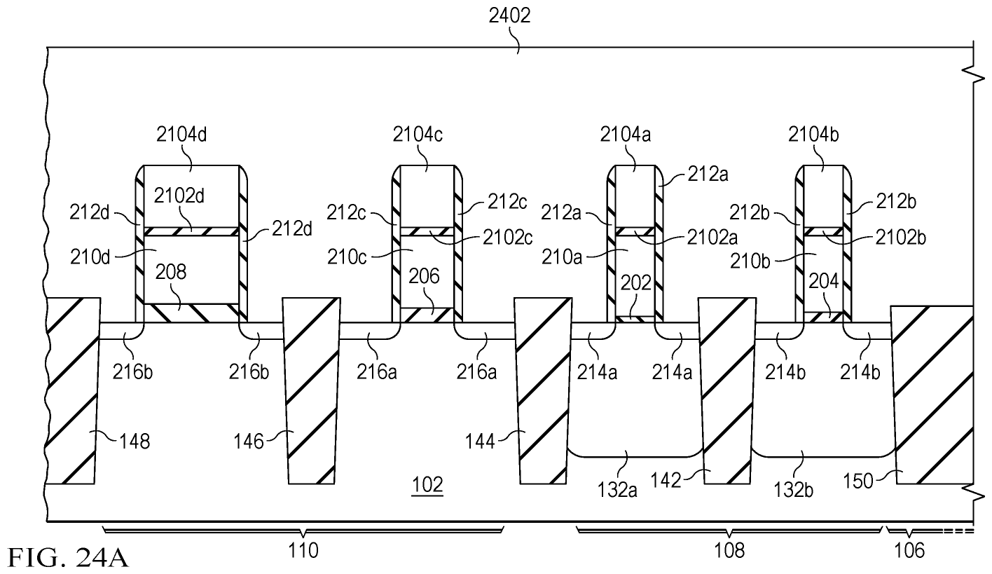

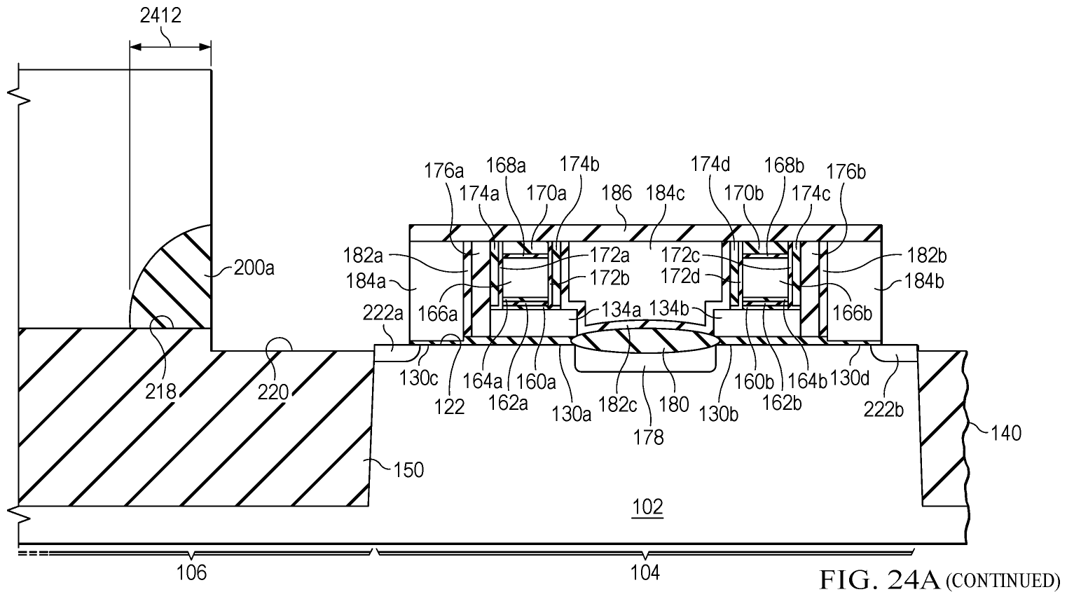

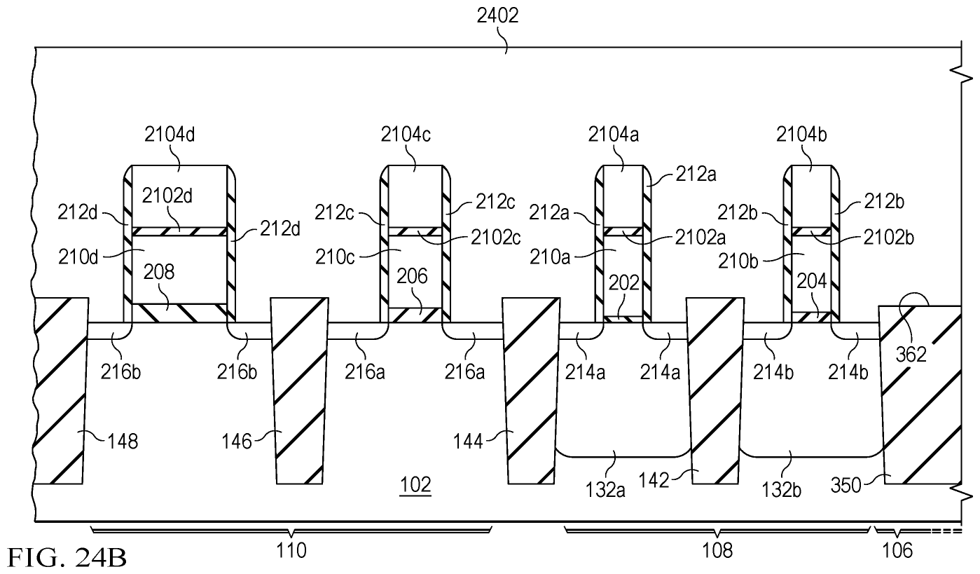

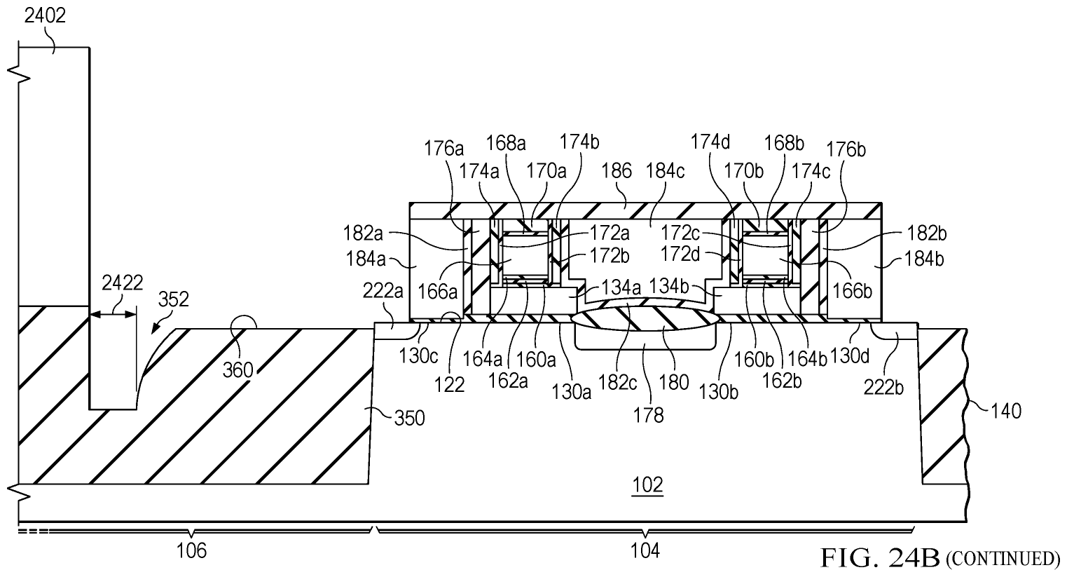

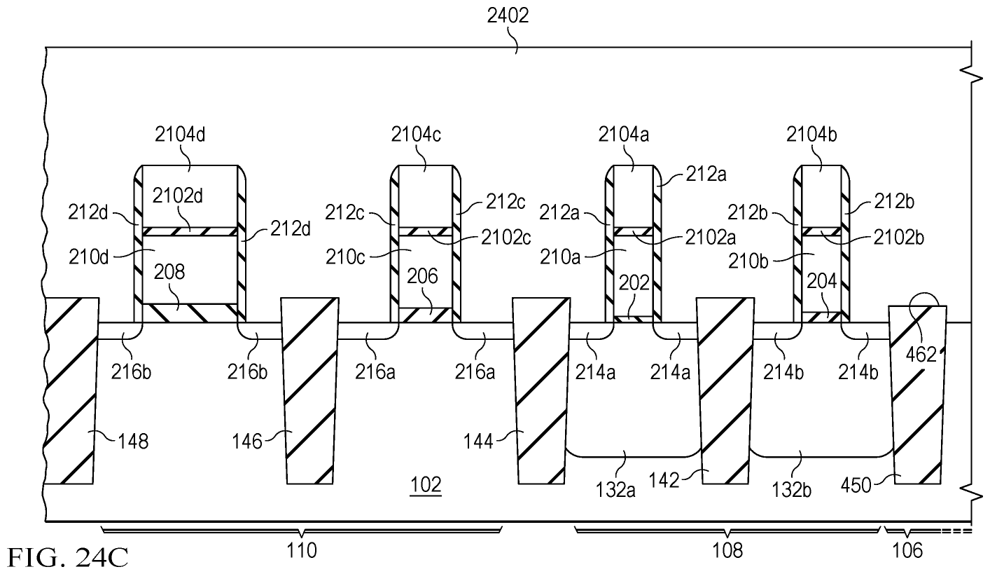

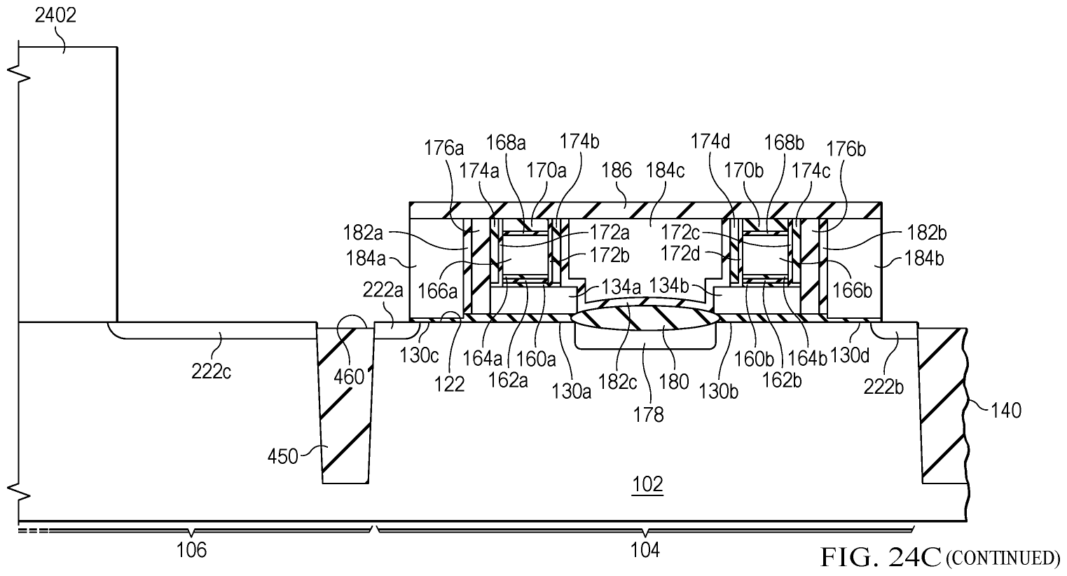

Referring to FIGS. 24A, 24B, and 24C, the protective dielectrics 200a, 200b are at least partially removed. In each of FIGS. 24A, 24B, and 24C, a photoresist 2402 is deposited (e.g., by spin-on) over the semiconductor substrate 102 and patterned using photolithography to expose the protective dielectrics 200a, 200b and the protective dielectric layer 186 in the flash memory region 104. Although the subsequent description of FIGS. 24A, 24B, and 24C focuses on processing with respect to the protective dielectric 200a, such description may also apply to the protective dielectric 200b.

In FIG. 24A (which corresponds to FIG. 1), a misalignment of a photolithography process results in overlap 2412 of the photoresist 2402 and the protective dielectric 200a. The lateral edge of the protective dielectric 200a generally results from the sidewall 1612 of the photoresist 1602 in FIG. 16. The conductive layer 184 is patterned using the photoresist 1602 and has a sidewall corresponding to the sidewall 1612 of the photoresist 1602. This sidewall of the conductive layer 184 defines the sidewall of the protective dielectric 200a, as shown in FIG. 17, which is subsequently developed as shown in FIG. 20. Hence, the overlap 2412 may be considered an overlap of the photoresist 2402 in FIG. 24 and the photoresist 1602 in FIG. 16. This overlap 2412 may be the result of a misalignment of one or both of the photoresists 2402, 1602.

Using the photoresist 2402 as a mask, an etch process is performed to selectively remove exposed portions of the protective dielectric 200a. The etch process may include a dry etch and/or a wet etch. The etch process removes an exposed portion of the protective dielectric 200a that is adjoining the WLG electrode 184a and over the upper surface 122 of the semiconductor substrate 102 laterally between the WLG dielectric layer 130c and the isolation structure 150. The photoresist 2402 masks a portion of the protective dielectric 200a (e.g., in the overlap 2412) distal from the WLG electrode 184a and over the isolation structure 150 in the transition region 106. Hence, the masked portion of the protective dielectric 200a remains after the etch process. The remaining protective dielectric 200a may form a protrusion protruding vertically from the isolation structure 150 and in the transition region 106.

In some examples, such as when the protective dielectric 200a is or includes a same material as the isolation structure 150 (e.g., like silicon oxide), the etch process may also etch an exposed portion of the isolation structure 150 (e.g., after the exposed portion of the protective dielectric 200a has been removed). As a result, as illustrated, an upper surface 220 of the isolation structure 150 exposed to the etch process may be at a level below the upper surface 122 of the semiconductor substrate 102. Further, the isolation structure 150 may have an upper surface 218 that is masked, and which may underlie the remaining portion of the protective dielectric 200a and/or may be proximate to the pFET region 108 and/or nFET region 110, that is at a level above the upper surface 220 of the isolation structure 150. The upper surface 218 may be above, at, or below the upper surface 122 of the semiconductor substrate 102.

In FIG. 24B (which corresponds to FIG. 2), a misalignment of a photolithography process results in gap 2422 of the photoresist 2402 from the protective dielectric 200a. The lateral edge of the protective dielectric 200a generally results from the sidewall 1612 of the photoresist 1602 in FIG. 16 as described above. Hence, the gap 2422 may be considered a gap between the photoresist 2402 in FIG. 24 and the photoresist 1602 in FIG. 16. This gap 2422 may be the result of a misalignment of one or both of the photoresists 2402, 1602.

Using the photoresist 2402 as a mask, an etch process is performed to selectively remove exposed portions of the protective dielectric 200a. The etch process may include a dry etch and/or a wet etch. The etch process removes an exposed portion of the protective dielectric 200a that is adjoining the WLG electrode 184a and over the upper surface 122 of the semiconductor substrate 102 laterally between the WLG dielectric layer 130c and the isolation structure 350. The photoresist 2402 further exposes a portion of the isolation structure 350 (e.g., in the gap 2422) distal from the WLG electrode 184a in the transition region 106. Hence, no portion of the protective dielectric 200a remains after the etch process.

In some examples, such as when the protective dielectric 200a is or includes a same material as the isolation structure 350 (e.g., like silicon oxide), the etch process may also etch an exposed portion of the isolation structure 350. As a result, a recess 352 is formed in the isolation structure 350 corresponding to the gap 2422. The protective dielectric 200a may mask a portion of the isolation structure 150 proximate to the flash memory region 104 early in the etch process, and the etch process may therefore form the recess 352 in the isolation structure 150 that is not masked by the photoresist 2402 or the protective dielectric 200a early in the etch process. Further, as illustrated, an upper surface 360 of the isolation structure 350 exposed to the etch process (e.g., after the exposed portion of the protective dielectric 200a has been removed) may be at a level below the upper surface 122 of the semiconductor substrate 102. Further, the isolation structure 350 may have an upper surface 362 that is masked, and which may underlie the photoresist 2402 and/or may be proximate to the pFET region 108 and/or nFET region 110, that is at a level above the upper surface 360 of the isolation structure 350. The upper surface 362 may be above, at, or below the upper surface 122 of the semiconductor substrate 102.

In FIG. 24C (which corresponds to FIG. 3), a misalignment of a photolithography process may result in an overlap or a gap of the photoresist 2402 from the protective dielectric 200a, like described above. Using the photoresist 2402 as a mask, an etch process is performed to selectively remove exposed portions of the protective dielectric 200a. The etch process may include a dry etch and/or a wet etch. The etch process removes an exposed portion of the protective dielectric 200a that is adjoining the WLG electrode 184a and over the upper surface 122 of the semiconductor substrate 102 laterally between the WLG dielectric layer 130c and the isolation structure 450. The upper surface 122 of the semiconductor substrate 102 laterally between the isolation structures 450, 452 may act as an etch stop such that a recess is not formed in the semiconductor material of the semiconductor substrate 102 in the transition region 106, such as when a gap (like in FIG. 24B) occurs. A masked portion of the protective dielectric 200a may remain over the upper surface 122 of the semiconductor substrate 102 in the transition region 106 when an overlap (like in FIG. 24A) occurs.

In some examples, such as when the protective dielectric 200a is or includes a same material as the isolation structures 450, 452 (e.g., like silicon oxide), the etch process may also etch an exposed portion of the isolation structure 450. As a result, as illustrated, an upper surface 460 of the isolation structure 450 exposed to the etch process (e.g., after the exposed portion of the protective dielectric 200a has been removed) may be at a level below the upper surface 122 of the semiconductor substrate 102. Further, the isolation structure 452 may have an upper surface 462 that is masked by the photoresist 2402 that is at a level above the upper surface 460 of the isolation structure 450. The upper surface 462 may be above, at, or below the upper surface 122 of the semiconductor substrate 102.

With the protective dielectrics 200a, 200b at least partially removed as described with respect to FIGS. 24A, 24B, and 24C, n-type cell LDDs 222a, 222b are formed. The n-type cell LDDs 222a, 222b may be formed by implanting an n-type dopant into the semiconductor substrate 102 in the flash memory region 104 using the photoresist 2402 as a mask. Specifically with respect to FIG. 24C, residual n-type cell LDD 222c is formed in the transition region 106 between the isolation structures 450, 452. The residual n-type cell LDD 222c is formed in the semiconductor substrate 102 between the isolation structures 450, 452 exposed through the photoresist 2402. Concentrations of the dopants may be as described previously. After the implantation, the photoresist 2402 is removed, such as by ashing.

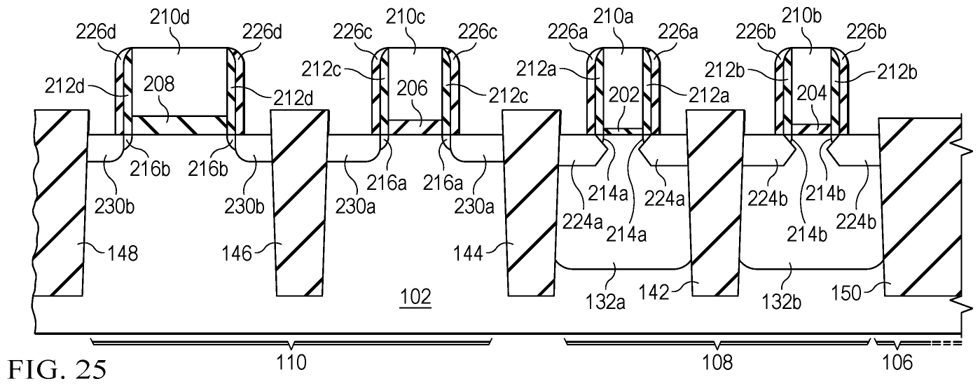

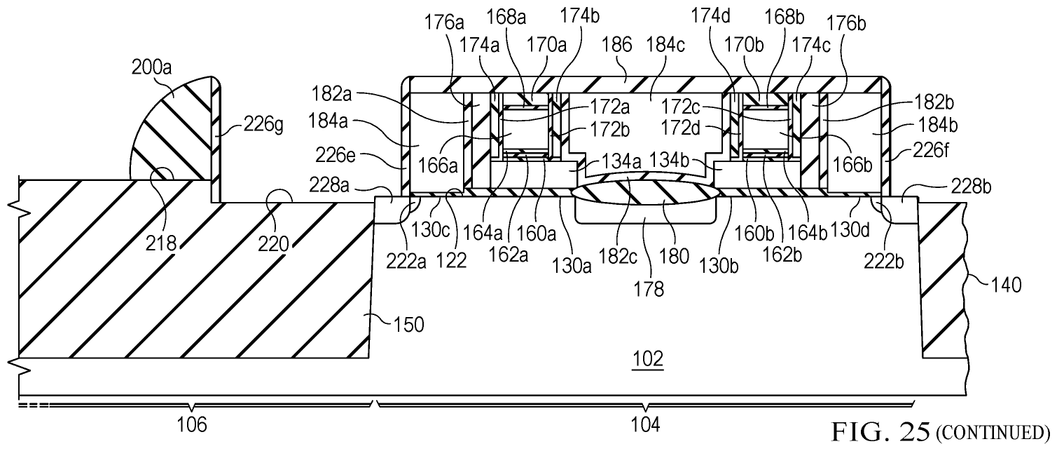

Referring to FIG. 25, embedded stressors 224a, 224b are then formed in the semiconductor substrate 102 in the pFET region 108. To form the embedded stressors 224a, 224b, respective recesses are formed in the semiconductor substrate 102. To form the recesses, a conformal hardmask layer is formed over the semiconductor substrate 102 in the flash memory region 104, transition region 106, and nFET region 110. The conformal hardmask layer may be or include silicon nitride, silicon oxynitride, the like, or a combination thereof. The conformal hardmask layer may be formed by conformally depositing and patterning the conformal hardmask layer. The conformal hardmask layer may be deposited by CVD, PECVD, ALD, or the like. The conformal hardmask layer may be patterned using photolithography and etching processes. Then, the recesses are formed in the semiconductor substrate 102 in the pFET region 108. The recesses are etched in the semiconductor substrate 102 where the embedded stressors are to be formed. The recesses may be formed using any appropriate etch process, which may be a wet or dry etch process. The etch process may be anisotropic and selective to (e.g., etching preferentially) a crystalline plane of the semiconductor substrate 102. The embedded stressors 224a, 224b are then formed in the recesses. The embedded stressors 224a, 224b may be formed using a selective epitaxial growth process. The embedded stressors 224a, 224b may be formed using metal-organic CVD (MOCVD), molecular beam epitaxy (MBE), LPCVD, or another epitaxy process. After forming the embedded stressors 224a, 224b, the conformal hardmask layer is removed. The conformal hardmask layer may be removed by an etch process selective to the material of the conformal hardmask layer, which may be a wet or dry etch process. Removal of the conformal hardmask layer may also remove the hardmask layers 2104a, 2104b, 2104c, 2104d. For example, the conformal hardmask layer and the first hardmask layers 2104a-2104d may be a same material that is removed by a same etch process.

Then, second gate dielectric spacers 226a, 226b, 226c, 226d are formed along sidewalls of the first gate dielectric spacers 212a, 212b, 212c, 212d. The second gate dielectric spacers 226a-226d may be formed by depositing a layer of the material of the second gate dielectric spacers 226a-226d conformally over the semiconductor substrate 102 and anisotropically etching the layer such that the second gate dielectric spacers 226a-226d remain. Additionally, other dielectric spacers may be formed on and along other sidewalls, such as gate dielectric spacers 226e, 226f on and along the WLG electrodes 184a, 184b, respectively. Further, as shown in FIG. 25 and in FIG. 1, residual dielectric spacer 226g may be formed on and along a sidewall of the protective dielectric 200a. As shown in FIG. 2, residual dielectric spacer 226h may be formed on and along a sidewall of the recess 352 in the isolation structure 350. The second gate dielectric spacers 226a-226d may be any material described above with respect to those components. The layer may be deposited by CVD, PECVD, ALD, or the like.

NSD regions 228a, 228b, 230a, 230b are formed in the semiconductor substrate 102. The NSD regions 228a, 228b, 230a, 230b may be formed by masking (e.g., by a photoresist using photolithography) the transition region 106 and pFET region 108 and implanting an n-type dopant into the semiconductor substrate 102 in the flash memory region 104 and the nFET region 110. Concentrations of the dopants may be as described previously.

PSD regions are formed in the semiconductor substrate 102. The PSD regions may be formed by masking (e.g., by a photoresist using photolithography) the flash memory region 104, transition region 106, and nFET region 110 and implanting a p-type dopant into the semiconductor substrate 102 in the pFET region 108. Concentrations of the dopants may be as described previously.

A stress memorization technique may be implemented, such as in the nFET region 110. A stressor dielectric layer is formed over the semiconductor substrate 102, gate electrodes 210c, 210d, and gate dielectric spacers 212c, 212d, 226c, 226d in the nFET region 110. The stressor dielectric layer may be or include silicon nitride, the like, or a combination thereof. The stressor dielectric layer may be formed by conformally depositing and patterning the stressor dielectric layer. The stressor dielectric layer may be deposited by CVD, PECVD, ALD, or the like. The stressor dielectric layer may be patterned using photolithography and etching processes. An anneal process is performed with the stressor dielectric layer in the nFET region 110. The anneal process permits the lattice structure of the semiconductor substrate 102 to conform due to the stress induced by the stressor dielectric layer. The anneal process may also activate dopants implanted in previous processes. After the anneal process, the stressor dielectric layer is removed. The stressor dielectric layer may be removed by an etch process selective to the material of the stressor dielectric layer, which may be a wet or dry etch process.

Referrring to FIG. 1, metal-semiconductor compound 240a, 240b, 240c, 240d, 240e, 240f, 240g, 240h, 240i, 240j are formed. The metal-semiconductor compound 240a-240j may be formed by depositing a metal (e.g., Ni, Ti, Co, Pt) over the semiconductor substrate 102, such as by PVD, CVD, or the like. The metal is reacted with a semiconductor material, such as the semiconductor material of the semiconductor substrate 102, the semiconductor material of the embedded stressors 224a, 224b, and the semiconductor material (e.g., silicon, such as polysilicon) of the gate electrodes 210a, 210b, 210c, 210d. An anneal process may be used to cause the metal to react with a semiconductor material. Any unreacted metal may be removed, such as by an etch selective to the metal.

A dielectric layer 242 is formed over the semiconductor substrate 102, and contacts 244a, 244b, 244c, 244d, 244e, 244f are formed through the dielectric layer 242. The dielectric layer 242 may include any sub-layers and/or materials as described above. The dielectric layer 242 may be deposited using CVD, PECVD, ALD, or the like. The dielectric layer 242 may be planarized, such as by a CMP.

To form the contacts 244a-244f, respective openings may be formed through the dielectric layer 242 to the metal-semiconductor compound 240a-240f using appropriate photolithography and etching processes. A metal(s) of the contacts 244a-244f are deposited in the openings through the dielectric layer 242. The metal(s) may be deposited using an appropriate deposition process(es), such as CVD, PVD, or the like. Any excess metal(s) may be removed, such as by a CMP and/or by patterning using photolithography and etch processes.

Although various examples have been described in detail, it should be understood that various changes, substitutions, and alterations can be made therein without departing from the scope defined by the appended claims.

What is claimed is:

1. An integrated circuit (IC), comprising:
a flash memory bit structure on a semiconductor substrate, the flash memory bit structure comprising a word line structure and a first oxide layer disposed between the semiconductor substrate and the word line structure, the first oxide layer being free of nitridation; and
a transistor structure on the semiconductor substrate, the transistor structure including a gate structure and a gate oxide layer including nitridation, the gate oxide layer being over the semiconductor substrate, the gate structure being over the gate oxide layer.

2. The IC of claim 1, wherein the flash memory bit structure further comprises:
a floating gate structure, the word line structure being located at a first side of the floating gate structure;
an erase gate structure located at a second side of the floating gate structure opposite the first side; and
a second oxide layer disposed between the erase gate structure and the floating gate structure, the second oxide layer being free of nitridation.

3. The IC of claim 1, wherein the flash memory bit structure further comprises:
a floating gate structure;
a control gate structure over the floating gate structure;
a second oxide layer disposed between the floating gate structure and the word line structure, the second oxide layer being free of nitridation; and
a nitride layer over the floating gate structure and disposed between the second oxide layer and the control gate structure.

4. The IC of claim 1, wherein the word line structure includes polysilicon.

5. The IC of claim 1 further comprising a transition region between the flash memory bit structure and the transistor structure, the transition region including:
an isolation structure in the semiconductor substrate; and
an oxide protrusion over the isolation structure extending vertically from an upper surface of the isolation structure.

6. The IC of claim 1 further comprising a transition region between the flash memory bit structure and the transistor structure, the transition region including an isolation structure in the semiconductor substrate, the isolation structure having a recess from an upper surface of the isolation structure.

7. The IC of claim 1 further comprising a transition region between the flash memory bit structure and the transistor structure, the transition region including:
a first isolation structure in the semiconductor substrate, the first isolation structure proximate the transistor structure;
a second isolation structure in the semiconductor substrate, the second isolation structure proximate the flash memory bit structure; and
a portion of the semiconductor substrate extending between the first isolation structure and the second isolation structure, the portion of the semiconductor substrate surrounding the flash memory bit structure.

8. The IC of claim 1, wherein the transistor structure includes a p-channel transistor with a SiGe structure.

9. A method, comprising:
forming a flash memory bit structure on a semiconductor substrate, forming the flash memory bit structure including:
forming a floating gate structure over the semiconductor substrate;
forming a first oxide layer at a first side of the floating gate structure; and
forming a word line structure on the first oxide layer, the first oxide layer being between the word line structure and the semiconductor substrate; and
after forming the word line structure, forming a gate oxide layer of a transistor structure on the semiconductor substrate.

10. The method of claim 9, wherein forming the word line structure includes:
depositing a polysilicon layer over the semiconductor substrate and on the first oxide layer; and
patterning the polysilicon layer into the word line structure.

11. The method of claim 9, further comprising nitriding the gate oxide layer.

12. The method of claim 11, wherein the nitriding is blocked from reaching the first oxide layer, at least in part, by the word line structure formed on the first oxide layer.

13. The method of claim 11, wherein after nitriding the gate oxide layer, the first oxide layer is free of nitridation.

14. The method of claim 9, wherein forming the gate oxide layer includes oxidizing an upper surface of the semiconductor substrate.

15. The method of claim 9, wherein forming the flash memory bit structure further includes:
forming a control gate structure over the floating gate structure;
forming a nitride layer along a sidewall of the control gate structure; and
forming a second oxide layer along a sidewall of the nitride layer, the second oxide layer being disposed between the word line structure and the nitride layer, wherein after nitriding the gate oxide layer, the second oxide layer is free of nitridation.

16. The method of claim 9, wherein forming the flash memory bit structure further includes:
forming a second oxide layer at a second side of the floating gate structure opposite the first side of the floating gate structure, the second oxide layer being on a sidewall of the floating gate structure; and
forming an erase gate structure on the second oxide layer.

17. The method of claim 16, wherein after nitriding the gate oxide layer, the second oxide layer is free of nitridation.

18. The method of claim 9 further comprising:
forming an isolation structure in the semiconductor substrate in a transition region between the flash memory bit structure and the transistor structure, wherein forming the word line structure includes patterning the word line structure, the isolation structure being exposed by patterning the word line structure;
forming a protective oxide on a sidewall of the word line structure and extending over the isolation structure that was exposed by patterning the word line structure;
forming a gate structure over the gate oxide layer; and
after forming the gate structure, etching the protective oxide, wherein a photoresist used in the etching has an opening defined in part by a photoresist sidewall, a gap being laterally between the photoresist sidewall and the protective oxide laterally distal form the word line structure, the opening exposing the protective oxide and a portion of the isolation structure, the etching forming a recess in the isolation structure.

19. The method of claim 9 further comprising:
forming an isolation structure in the semiconductor substrate in a transition region between the flash memory bit structure and the transistor structure, wherein forming the word line structure includes patterning the word line structure, the isolation structure being exposed by patterning the word line structure;
forming a protective oxide on a sidewall of the word line structure and extending over the isolation structure that was exposed by patterning the word line structure;
forming a gate structure over the gate oxide layer; and
after forming the gate structure, etching the protective oxide, wherein a photoresist used in the etching has an opening defined in part by a photoresist sidewall, the photoresist sidewall being over the protective oxide, the etching forming a protrusion oxide protruding from the isolation structure, the protrusion oxide remaining from the protective oxide after the etch.

20. A method, comprising:
forming a floating gate structure over a semiconductor substrate;
forming an oxide-nitride-oxide stack over the floating gate structure;
forming a control gate structure over the oxide-nitride-oxide stack;
forming a word line oxide layer over the semiconductor substrate laterally on a first side of the floating gate structure;
forming a word line structure over the word line oxide layer;
after forming the word line structure, forming a gate oxide layer; and
forming a gate electrode over the gate oxide layer.

21. The method of claim 20, further comprising nitriding the gate oxide layer before forming the gate electrode over the gate oxide layer.

22. The method of claim 21, wherein after nitriding the gate oxide layer, the word line oxide layer is free of nitridation.

23. The method of claim 20, further comprising:
forming a tunnel oxide layer on the floating gate structure on a second side of the floating gate structure opposite the first side; and
forming an erase gate structure on the tunnel oxide layer, wherein the gate oxide layer is formed after the erase gate structure is formed.

24. The method of claim 23, further comprising nitriding the gate oxide layer before forming the gate electrode over the gate oxide layer.

25. The method of claim 24, wherein after nitriding the gate oxide layer, the tunnel oxide layer is free of nitridation.

26. The method of claim 20, wherein:
the gate oxide layer is a first gate oxide layer of a plurality of gate oxide layers; and
remaining gate oxide layers of the plurality of gate oxide layers are formed in parallel with at least part of or after formation of the first gate oxide layer.
